(19) United States
(12) Patent Application Publication
(10) Pub. No.: US 2014/0195183 A1
(43) Pub. Date: Jul. 10, 2014

(54) METHOD AND SYSTEM FOR ESTIMATING A DIFFUSION POTENTIAL OF A DIFFUSIVE PROPERTY

(71) Applicants: Harish Chandra Rajput, Kelowna (CA); Andrew Labun, Kelowna (CA); Thomas Edward Johnson, Lake Country (CA)

(72) Inventors: Harish Chandra Rajput, Kelowna (CA); Andrew Labun, Kelowna (CA); Thomas Edward Johnson, Lake Country (CA)

(73) Assignee: THE UNIVERSITY OF BRITISH COLUMBIA, Kelowna, BC (CA)

(21) Appl. No.: 14/237,259

(22) PCT Filed: Apr. 5, 2012
(86) PCT No.: PCT/CA2012/000337

§ 371 Date: Feb. 5, 2014

Related U.S. Application Data
(60) Provisional application No. 61/472,522, filed on Apr. 6, 2011.

(51) Int. Cl. G01R 31/28

(52) U.S. Cl. CPC G01R 31/2851
USPC 702/65

(57) ABSTRACT

Described herein are a method, system, and computer readable medium for estimating a diffusion potential (such as temperature) of a diffusive property (such as thermal energy, referred to herein as “heat”). The method includes modeling as a circuit a diffusion region having two subregions to which the diffusive property is introduced at different rates and through which the diffusive property linearly diffuses. The nodes of the circuit include a dividing node that divides branches of the circuit that model the two subregions. A circuit potential at one of the nodes of the circuit corresponds to the diffusion potential at a location within the diffusion region. The diffusion potential at the location within the diffusion region is estimated by simulating operating of the circuit and determining the circuit potential at the node of the circuit.

### TECHNICAL FIELD

The present disclosure is directed at methods, systems, and techniques for estimating a diffusion potential, such as a thermal potential (colloquially referred to as “temperature”), of a diffusive property, such as thermal energy (colloquially referred to as “heat”). More particularly, the present disclosure is directed at estimating a diffusion potential obeying linear diffusion; that is, a diffusion potential whose gradient is a force that is linearly proportional to the flux of the underlying diffusive property.

### BACKGROUND

Linear diffusion under various names is used to describe the flux of different diffusive properties. For example, Fick's law describes diffusion of a number of molecules of one gas species within a mixture of several species (the potential is called the concentration or partial pressure); Ohm's law describes the diffusion of electric charge (the electric flux is called electric current, the electric potential is called the voltage); and Fourier's law describes the diffusion of heat in conductors (the thermal potential is called the temperature). The constant of proportionality between the gradient and the flux is called the conductance, e.g. thermal conductance in Fourier's law and electrical conductance in Ohm's law, or diffusivity in Fick's law.

In particular, the effects of heat and its diffusion are becoming increasingly problematic when manufacturing and using integrated circuits (ICs). The dimensions of ICs manufactured using complementary metal-oxide semiconductor (CMOS) technology continue to shrink, which increases their power density. As ICs shrink, their power density tends to increase for two reasons. First, the ICs generally shrink at a rate that is faster than the rate at which their supply voltages decrease. Second, the frequency at which ICs are operated tends to increase as they shrink, resulting in increasing power losses related to high frequency switching.

Research and development accordingly continue into techniques to address the problems that heat and its diffusion pose to ICs. More generally, research and development continue into ways to more generally apply theories describing linear diffusion to solve various problems.

### SUMMARY

According to a first aspect, there is provided a method for estimating a diffusion potential of a diffusive property. The method comprises modeling as a circuit a diffusion region comprising two subregions to which the diffusive property is introduced at different rates and through which the diffusive property linearly diffuses, wherein the nodes of the circuit comprise a dividing node dividing branches of the circuit modeling the two subregions and wherein a circuit potential at one of the nodes of the circuit corresponds to the diffusion potential at a location within the diffusion region; and estimating the diffusion potential at the location within the diffusion region by simulating operation of the circuit and determining the circuit potential at the one of the nodes of the circuit.

The diffusive property may be steady-state temperature. The diffusion region may be a pinched-off channel of a MOSFET

The circuit may be any one of an electric circuit, a hydraulic circuit, and a thermal circuit.

When an electric circuit is used to thermally model the channel, the circuit may comprise a voltage source connected between a common node and the dividing node, the dividing node corresponding to the pinch-off point of the channel; and source and drain branches each connected in parallel between the pinch-off node and the common node. Each of the source and drain branches comprises a first resistor having one end connected to the pinch-off node; and a parallel branch comprising a current source and a second resistor connected together in parallel, the parallel branch connected in series between the other end of the first resistor and the common node.

The node between the first resistor of the source branch and the parallel branch of the source branch may correspond to the source end of the channel, and the node between the first resistor of the drain branch and the parallel branch of the drain branch may correspond to the drain end of the channel.

Portions of the MOSFET between the source and drain ends of the channel and a source netlist node and a drain netlist node of the MOSFET may be respectively modeled as a source netlist branch and a drain netlist branch each comprising a pair of current sources; and a resistive pi network connected in parallel between the pair of current sources, wherein the pair of current sources and the resistive pi network of the source netlist branch are connected in parallel across the source branch and the pair of current sources and the resistive pi network of the drain netlist branch are connected in parallel across the drain branch.

The node between the first resistor of the source branch and the parallel branch of the source branch may correspond to a source netlist node of the MOSFET, and the node between the first resistor of the drain branch and the parallel branch of the drain branch may correspond to a drain netlist node of the MOSFET.

Following estimating the diffusion potential at the location within the diffusion region, the method may also comprise analytically determining the diffusion potential at an additional location within the diffusion region that corresponds to positions between the nodes of the circuit.

Each of the nodes of the circuit may correspond to the diffusion potential at a different location within the diffusion region.

The diffusive property may be introduced to the diffusion region by being generated within the diffusion region. Alternatively or additionally, the diffusive property may be introduced to the diffusion region by being transported to the diffusion region.

According to another aspect, there is provided a method for estimating temperature within a pinched-off channel of a MOSFET. The method comprises modeling the thermal properties of the channel as an electric circuit comprising a dividing node corresponding to the pinch-off point of the channel and branches modeling subregions of the channel separated from each other by the pinch-off point, wherein a voltage at one of the nodes of the circuit corresponds to the temperature at a location within the channel; and estimating the temperature at the location within the channel by simulating operation of the circuit and determining the voltage at the one of the nodes of the circuit.

According to another aspect, there is provided a system for estimating a diffusion potential of a diffusive property. The system comprises a controller; and a computer readable medium, communicatively coupled to the controller, having encoded thereon statements and instructions to cause the controller to perform a method according to any aspects described above.

According to another aspect, there is provided a computer readable medium having encoded thereon statements and instructions to cause a controller to perform a method according to any aspects described above.

This summary does not necessarily describe the entire scope of all aspects. Other aspects, features and advantages will be apparent to those of ordinary skill in the art upon review of the following description of specific embodiments.

### BRIEF DESCRIPTION OF THE DRAWINGS

In the accompanying drawings, which illustrate one or more exemplary embodiments:

FIGS. 1(a) and (b) are schematics of layouts of MOSFETs to which an embodiment of a method for estimating a diffusion potential can be applied.

FIG. 2 is a schematic of a resistor illustrating heat flux entering and leaving a differential slice of the resistor.

FIG. 3 is a sectional view of an nMOSFET to which an embodiment of the method referred to in respect of FIGS. 1(a) and (b) can be applied.

FIG. 4 shows a conductive channel of the nMOSFET of FIG. 3.

FIG. 5 shows a portion of the channel of FIG. 4 from the source end of the channel to the pinch-off point of the channel.

FIG. 6 shows a portion of the channel of FIG. 4 from the pinch-off point of the channel to the drain end of the channel.

FIG. 7 shows an embodiment of an M-Network, used to thermally model the channel of FIG. 4.

FIG. 8 shows a method into which reliability verification can be incorporated, according to another embodiment.

FIG. 9 shows the layout of an exemplary nMOSFET.

FIGS. 10(a) to (j) are graphs of channel temperature vs. channel length of the nMOSFET of FIG. 9, generated in accordance with one embodiment of the method referred to in respect of FIGS. 1(a) and (b).

FIGS. 11 and 12 are schematics of an embodiment of the M-Network used to thermally model the channel, source and drain of a MOSFET.

FIG. 13 is an embodiment of a method for estimating a diffusion potential.

FIG. 14 is an embodiment of a system for estimating a diffusion potential.

### DETAILED DESCRIPTION

Directional terms such as “top”, “bottom”, “left”, “right”, “front”, and “rear” are used in the following description for the purpose of providing relative reference only, and are not intended to suggest any limitations on how any article is to be positioned during use, or to be mounted in an assembly or relative to an environment.

Electromigration in ICs can prejudice their reliability. Electromigration refers to the migration and resulting degradation of portions of metallic conductors over time in response to both current flowing through the conductors and to relatively high temperatures to which the conductors are exposed. Since current flowing through a conductor generates heat, high temperatures and current are unfortunately closely linked in practice.

The degree to which ICs are susceptible to electromigration depends on their layout. Accurately predicting the effect an IC's layout will have on its operating temperature can be difficult. Unfortunately, if a problem with an IC's layout is found only after tape-out, the costs in terms of both time and money of subsequently changing the layout to rectify the problem are relatively high.

Some of the embodiments discussed herein are directed at a method and system for estimating thermal potential, also referred to herein as “temperature”, of thermal energy, also referred to herein as “heat”. These embodiments use a type of electric circuit model referred to as an “M-Network” to model the heat generation and subsequent diffusion that occur within the channel of a MOSFET. The M-Network can accordingly be used to determine the steady-state (DC) temperature at various points within the channel.

However, in alternative embodiments, the diffusion potentials of different types of diffusive properties may be estimated, so long as the diffusive property is introduced to at least two subregions within the region through which the diffusive property may diffuse (“diffusion region”), and so long as the diffusive property diffuses linearly through the diffusion region. For example, in one alternative embodiment a tube of length L is open at both ends and has an inner surface that is coated for half its length with a catalyst. The tube is filled with a reactive gas and sustains a chemical reaction on its interior surface that releases a gaseous product. If the tube forms part of a larger system of connected tubes, it may be convenient to model the tube as a single entity with two ends. The rate of generation of the gaseous product and its concentration, which is the diffusion potential, results from chemical activity within one subregion of the tube that corresponds to the portion of the tube coated with the catalyst, whereas the uncoated portion of the tube corresponds to another subregion. Fluxes of gaseous product diffusing out of the two ends of the tube are unequal. In this example, the underlying diffusive property is the number of particles of the gaseous product. Additionally, in an embodiment in which the tube is open to the atmosphere at both ends, the concentrations of gaseous product, measured in ppm, differ at the two ends of the tube. In another alternative embodiment, a long iron bar is fixed at both ends to permafrost, but one end of the bar is in shadow and the other is exposed to sunlight. Heat is accordingly introduced to the subregion that corresponds to the portion of the bar exposed to sunlight, while the other subregion of the bar is the portion that is in the shadow. Differing amounts of heat are conducted through the two ends of the bar into the bodies that anchor it, making one side more likely to melt the permafrost. In this embodiment, the temperature of the bar if the diffusion potential and the diffusive property is heat. In another alternative embodiment, fertiliser is transported into (e.g.: via seeping) a sluggish stream at a point and diffuses unevenly into the water, leading to an algae growth rate that is greater downstream than upstream. The diffusion potential in this example is the concentration of algae in grams per litre, while the diffusive property is the number of particles of algae. One subregion of the stream is upstream from the point at which the fertiliser seeps into the stream, while the other subregion is downstream. In another alternative embodiment, an electrically-conducting wire that acts as a resistor and across which a fixed voltage is maintained by an external circuit is vertically embedded in a porous dielectric insulator, the lower end of which is soaked in water, such that some electrical current leaks to electrical ground through the soaked, lower portion of the insulator. If the water level in the soaked insulator rises, even more electric current leaks out of the wire. In this embodiment, the diffusion potential is voltage, the diffusive property is electric charge, one subregion is the lower end of the insulator, while the other subregion is the end of the insulator that is not soaked in water.

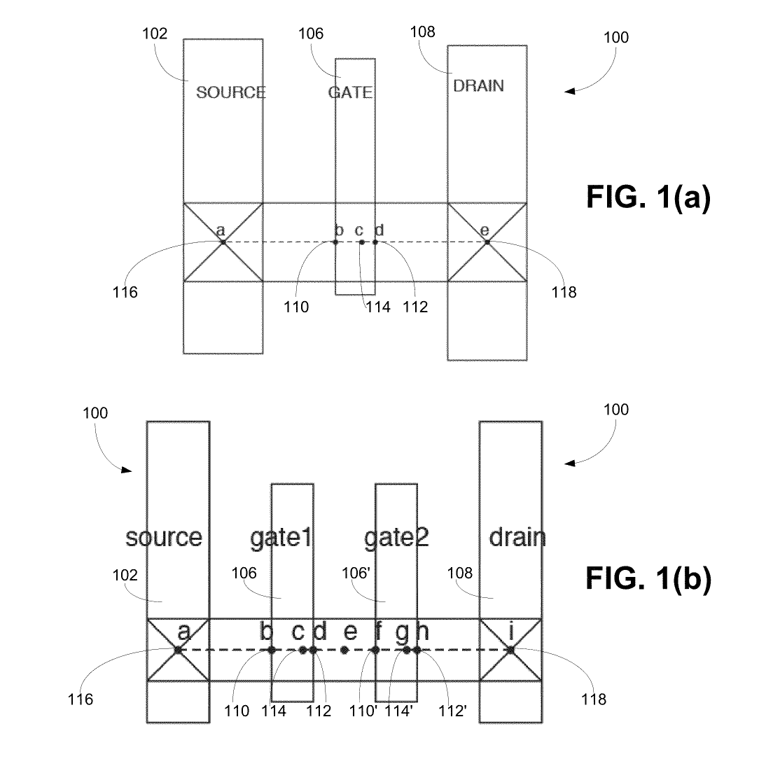

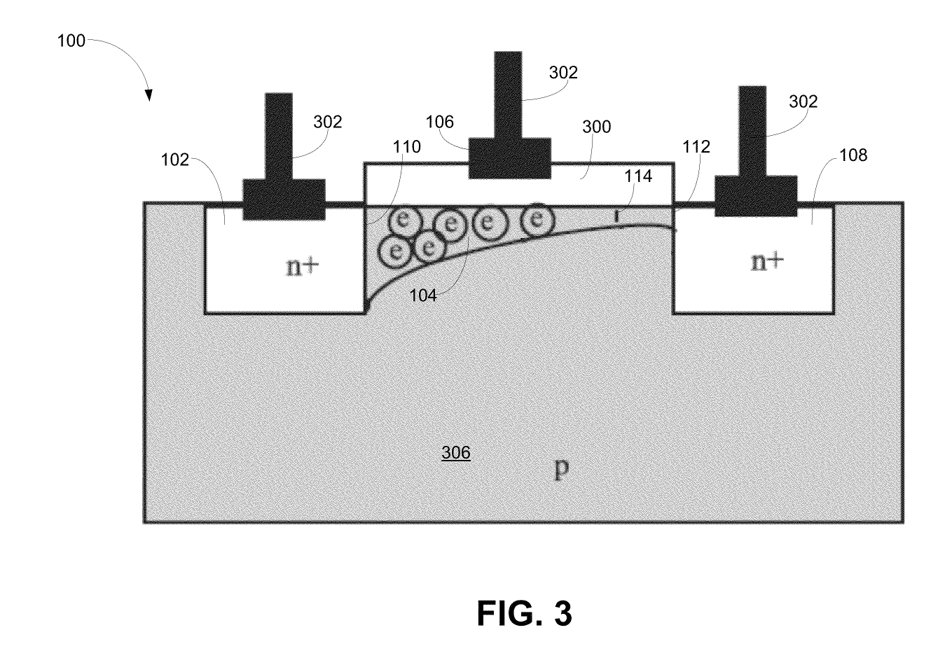

As an example of one embodiment, the following discussion describes how to estimate temperature (i.e. thermal potential) at various locations within a MOSFET. FIGS. 1(a) and (b) show layouts of exemplary MOSFETs 100 that are referred to in this discussion. The MOSFET 100 in FIG. 1(a) includes a source 102, a drain 108, and a gate 106 located between the source 102 and drain 108. When the MOSFET 100 is in operation, a channel 104 (not shown in FIG. 1(a), but shown in FIG. 3) conducts current between the source 102 and drain 108. The end of the channel 104 closest to the source 102 is referred to as the source end 110 of the channel 104, while the end of the channel 104 closest to the drain 108 is referred to as the drain end 112 of the channel 104. When the MOSFET 100 is operating in saturation mode, the pinch-off point 114 of the channel 104 is between the source and drain ends 110,112. FIG. 1(a) also identifies where, for the purposes of a common list of two-port networks (commonly referred to as a “netlist”) and for circuit simulation using a simulator such as SPICE, the nodes representing the source 102 and drain 108 of the MOSFET are: one location 116 on the source 102 represents the netlist node for the source 102 (“source netlist node 116”), while another location 118 on the drain 108 represents the netlist node for the drain 108 (“drain netlist node 118”).

FIG. 1(b) shows two series, or stacked, MOSFETs 100′. The MOSFETs 100′ include the source 102, drain 108, gate 106, source netlist node 116, and drain netlist node 118 of the MOSFET 100 shown in FIG. 1(a), and also include another gate 106′ having its own channel (not shown) with its own source end 110′, drain end 112′, and pinch-off point 114′. Heat diffusion in both the channel of the MOSFET 100 in FIG. 1(a) and the channels of the stacked MOSFETs 100′ of FIG. 1(b) can be estimated using the embodiments developed and discussed in this disclosure.

FIG. 3 shows an n-type MOSFET 100 of similar layout as that of FIG. 1(a). The MOSFET 100 of FIG. 3 is operating in saturation mode. In addition to showing the source 102, gate 106, and drain 108, the asymmetric nature of the channel 104 is evident. The source end 110 of the channel 104 has the largest cross-sectional area of any cross-section of the channel 104, and the cross-sectional area shrinks until the channel 104's pinch-off point 114. FIG. 3 also shows the MOSFET 100's substrate 306, an oxide layer 300 between the gate 106 and the channel 104, and vias 302 connected to the source 102, gate 106, and drain 108.

### Heat Equation

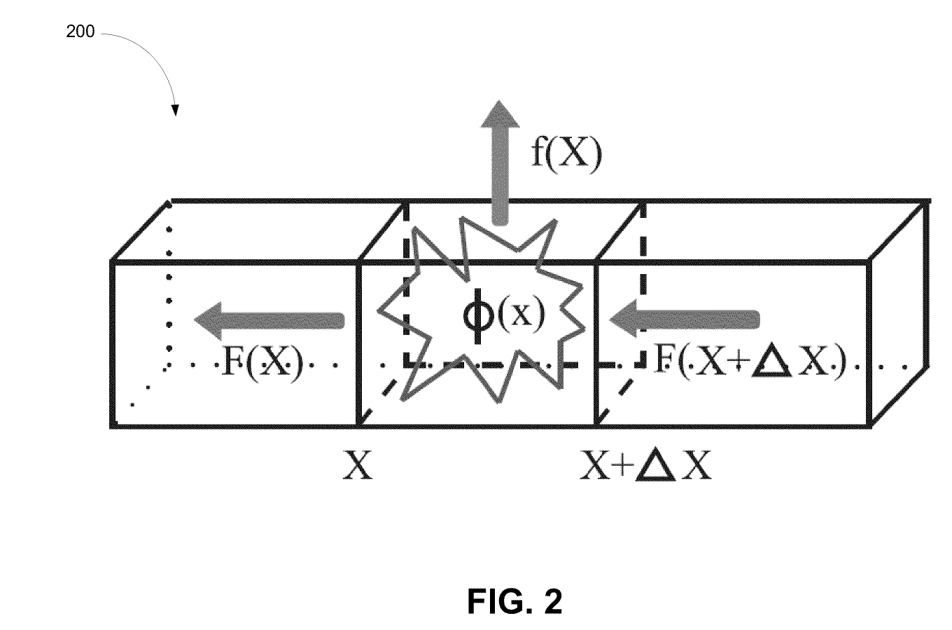

Before modeling the channel 104, a model for heating in a resistor 200, as shown in FIG. 2, is derived. For the purposes of this model, the resistor 200 is presumed to be of uniform width and composition, and to have constant temperature over any cross-section taken perpendicular to its length.

The heat per unit length in a differential slice of the resistor 200 is mCₚT(x)Δx, where the length of the differential slice is Δx, T(x) is the temperature along the resistor 200's length, m is the mass of the resistor 200 per unit length, and Cₚ, is the heat capacity of the resistor 200. The time rate of change of the heat is then given by

$${mC}_{p} \frac{\partial T}{\partial t} Δ x = F ( x + Δ x ) - F ( x ) + φ ( x ) Δ x - f ( x ) Δ x \qquad ( 1 )$$

where F(x) is the diffusive heat flux. The heat flux is oriented along the resistor 200's length and is related to the temperature gradient by Fourier's law of heat conduction:

$$F ( x ) = {G}^{long} \frac{\partial T ( x )}{\partial x} \qquad ( 2 )$$

where G^{long} is the longitudinal thermal conductance of the resistor 200.

The Joule heat generated per unit length of the resistor 200 is given by φ=Iᵣₘₛ²R; R is the resistor 200's electrical resistance per unit length, which is assumed to be constant within the resistor 200, and Iᵣₘₛ is the time-averaged rms current flowing through the resistor 200. The function ƒ(x) in Equation 1 models the heat flux through the sides of the resistor 200 to the environment, which is at a reference temperature T^{ref}. If diffusive heat flux passes through the sides of the resistor 200 to the environment, which is held constant at the reference temperature T^{ref} (established, for example, by a full-chip temperature simulation including device heating), then a lateral thermal conductance G^{lat} per unit length of the resistor 200 may be defined as follows:

ƒ(x)=G^{lat}T(x)−T^{ref} (3)

### Heat Generation in MOSFETs

When the MOSFET 100 is on and is in operation, charge carriers move from the source 102 to the drain 108 and in this process lose energy due to processes such as collisions, scattering, phonon-electron interaction, etc. The dissipated energy is released in the form of heat and leads to an increase in the MOSFET 100's temperature. As mentioned above in respect of FIG. 3, when the MOSFET 100 is operating in saturation mode the channel 104 is asymmetric and decreases in cross-sectional area from its source end 110 to the pinch-off point 114. Between the pinch-off point 114 and the drain end 112 the channel 104's cross-sectional area is roughly constant. The discussion above concerning the resistor 200 can be applied to the channel 104 by modeling the channel 104 as a resistor of variable cross-sectional area. Heat generated in the channel 104 by current flow can be approximated as Joule heating analogous to what occurs in the resistor 200.

As discussed below, the one-dimensional heat equation (Equation 1) can be applied to the thermal model of the MOSFET 100 and solved analytically to give a closed-form expression for the temperature of the channel 104 from the source end 110 to the drain end 112. The embodiments discussed herein use the BSIM3 MOSFET model as created by the BSIM Group in the Department of Electrical Engineering and Computer Sciences at the University of California, Berkeley, and are applicable to technology nodes equalling or exceeding 180 nm. However, in other embodiments (not depicted) alternative semiconductor models can be used as well, and technology nodes less than 180 nm may be modeled. Additionally, while the present disclosure is directed at modeling diffusion within the channel 104 of the n-type MOSFET 100, in alternative embodiments different types of transistors may be modeled. For example, p-type MOSFETs, HEMTs, BJTs, and FinFETs may be modeled.

### Channel Geometry for Thermal Model

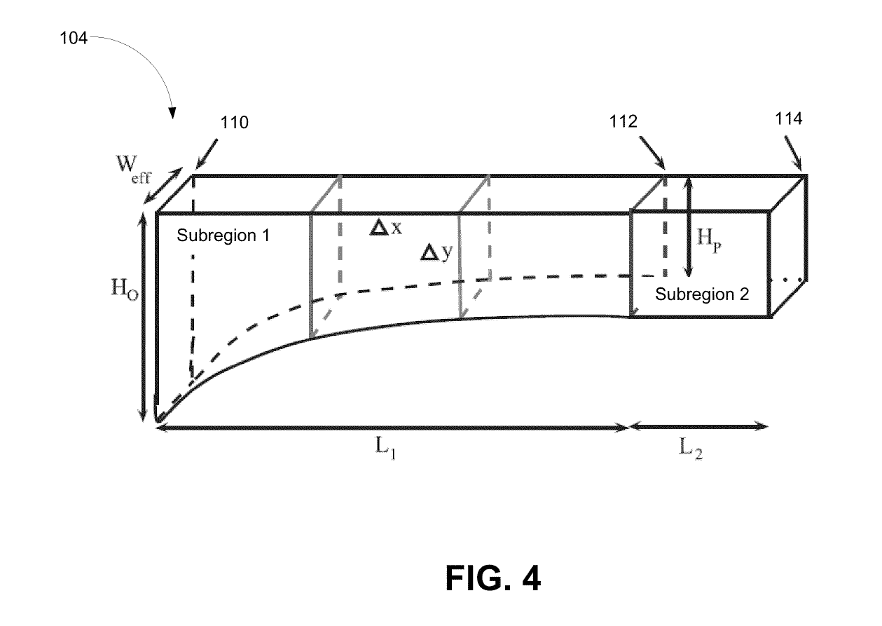

FIG. 4 shows the channel 104 of the MOSFET 100. In the saturation region of operation the channel 104 shrinks near the drain end 112 and the drain current becomes almost constant with respect to I_{ds}. The drain current flows through the depletion region at the drain end 112. When the MOSFET 100 is operating in saturation mode the channel is modeled as comprising two separate regions, Subregion 1 and Subregion 2.

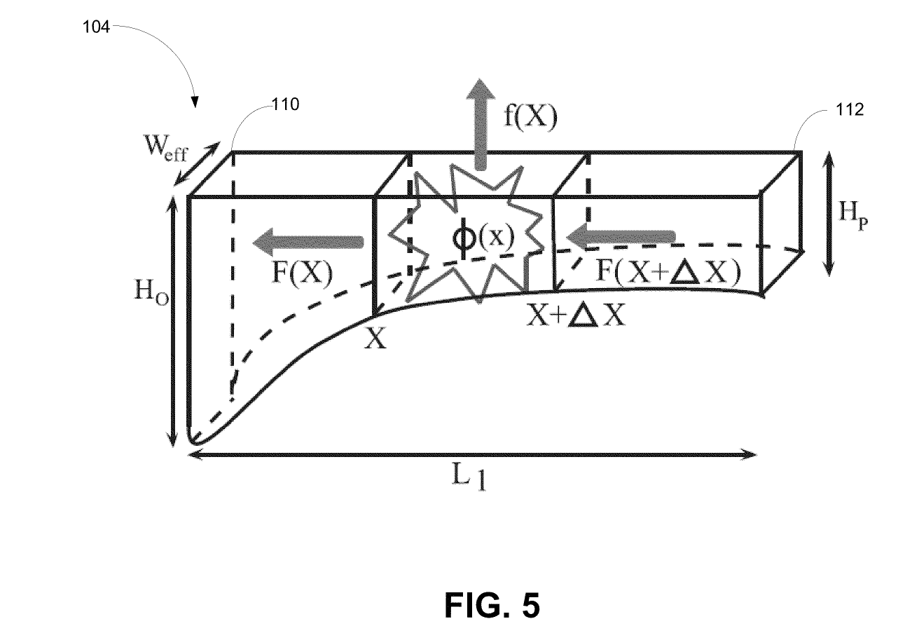

As shown in FIG. 5, Subregion 1 is a channel of constant width W_{eff} and non-uniform height which tapers from the source end 110 to the pinch-off point 114. This subregion is approximated by an exponential function of the form y=Ae^{-αx} where y is the height and x is the length of the channel 104. An exponential function is selected for the model to lead to tractable analytic results. The parameters A and α in the exponential function are determined from the BSIM3 model parameters and correspond to the operating point of the MOSFET 100.

If L₁ is the length of the channel 104 between the source end 110 and the pinch-off point 114, H_{O} is the height of the channel 104 at the source end 110 and H_{P} is the height of the channel 104 at the pinch-off point 114, then

$$x = {L}_{1} ⇒ y = {H}_{P} \\ {H}_{P} = {H}_{O} {e}^{α {L}_{1}} ⇒ α = \frac{1}{{L}_{1}} ln ( \frac{{H}_{O}}{{H}_{P}} ) \\ y = {H}_{O} {e}^{- \{ \frac{1}{{L}_{1}} ln ( \frac{{H}_{O}}{{H}_{P}} ) \} x} \qquad ( 4 )$$

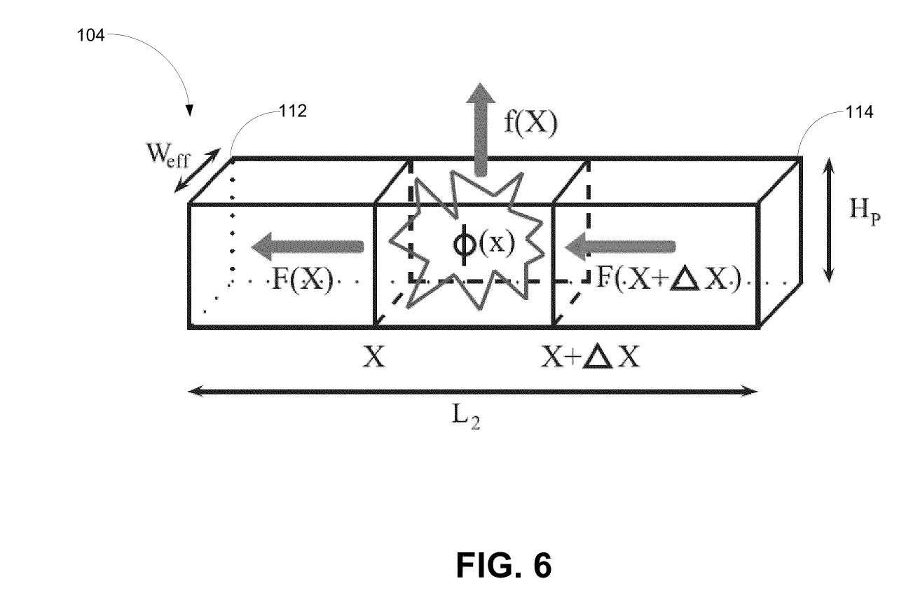

FIG. 6 depicts Subregion 2 of the channel 104, which corresponds to the portion of the channel 104 between the pinch-off point 114 and the drain end 112. In this subregion, the channel 104 cross-section is uniform and has width W_{eff} and height H_{P}. The length of Subregion 2 is denoted as L₂.

### Electrical Resistance

The resistance of Subregion 1 can be approximated by integrating the resistance of a differential slice of the channel 104 from the source end 110 to L₁:

$$\begin{matrix}{R}_{1} = {\int }_{0}^{L 1} \frac{ρ {e}^{α x}}{{W}_{eff} {H}_{O}} d x = \frac{ρ}{{W}_{eff} {H}_{O} α} ( {e}^{α {L}_{1}} - 1 ) & ( 5 ) \\ α = \frac{1}{{L}_{1}} ln ( \frac{{H}_{O}}{{H}_{P}} ) & ( 6 ) \\ {L}_{eff} = {L}_{1} + {L}_{2} & ( 7 )\end{matrix}$$

where
ρ=Electrical resistivity
H_{O}=Height of the channel 104 at the source end 110
H_{P}=Height of the channel 104 at pinch-off point 114
W_{eff}=Effective with of the channel 104
L₁=Length of the channel 104 between the source end 110 and the pinch-off point 114
L₂=Length of the channel between the pinch-off point 114 and the drain end 112
L_{eff}=Effective length of the channel 104

The effective length and width of the channel 104 can be approximated by:

$$\begin{matrix}{L}_{eff} = {L}_{Drawn} - 2 d L & ( 8 ) \\ {W}_{eff} = {W}_{Drawn} - 2 d W & ( 9 ) \\ dW = {W}_{int} + \frac{{W}_{l}}{{L}^{{W}_{ln}}} + \frac{{W}_{w}}{{W}^{{W}_{wn}}} + \frac{{W}_{wl}}{{L}^{{W}_{ln}} {W}^{{W}_{wn}}} & ( 10 ) \\ d L = {L}_{int} + \frac{{L}_{l}}{{L}^{{L}_{ln}}} + \frac{{L}_{w}}{{W}^{{L}_{wn}}} + \frac{{L}_{wl}}{{L}^{{L}_{ln}} {W}^{{L}_{wn}}} & ( 11 )\end{matrix}$$

where
L_{Drawn}=Layout drawn length of the MOSFET 100
W_{Drawn}=Layout drawn width of the MOSFET 100
Wᵢₙₜ, Lᵢₙₜ, Wₗ, W_{w}, W_{wl}, W_{wn}, Lₗ, L_{w}, L_{wn}, L_{wl}, are BSIM3 parameters

The electrical resistivity of the channel 104 can be approximated as

$$ρ = \frac{1}{{W}_{eff} {C}_{ox} {μ}_{eff}} \qquad ( 12 )$$

where
Cₒₓ=Capacitance of the oxide layer 300
μ_{eff}=Effective mobility of charge carriers

Subregion 2 has a uniform cross-sectional area. This can be considered as a uniform bar of length L₂, width W_{eff}, and height H_{P}. Its resistance is given by:

$${R}_{2} = \frac{ρ {L}_{2}}{{W}_{eff} {H}_{P}} \qquad ( 13 )$$

### Channel Height Models

The height of the channel 104 at the source end 110 can be approximated as the thickness of the inversion layer:

$$\begin{matrix}{H}_{O} = {t}_{inv} = \frac{k T}{\sqrt{\frac{{ɛɛ}_{o}}{2 {qN}_{A} {φ}_{s}}}} & ( 14 ) \\ {φ}_{s} = 2 \frac{k T}{q} ln ( \frac{{N}_{A}}{{n}_{i}} ) & ( 15 )\end{matrix}$$

where
k=Boltzmann's constant
T=Temperature
∈=Dielectric constant
∈ₒ=Permittivity of free space
q=Electron charge
N_{A}=Substrate doping concentration
nᵢ=Intrinsic silicon concentration
φₛ=Surface potential

The height of the channel 104 at the pinch-off point 114, H_{P}, can be approximated as follows:

$${R}_{1} + {R}_{2} = \frac{{V}_{DS}}{{I}_{sat}} \\ \frac{ρ ( {e}^{α {L}_{1}} - 1 )}{{W}_{eff} {H}_{O} α} + \frac{ρ {L}_{2}}{{W}_{eff} {H}_{P}} = \frac{{V}_{DS}}{{I}_{sat}} \qquad ( 16 )$$

Under the approximation H_{P}<<<H_{O},

$${H}_{P} = \frac{ρ {L}_{2} {I}_{sat}}{{V}_{DS} {W}_{eff}} \qquad ( 17 )$$

where
Iₛₐₜ=Electric current in saturation region of operation
V_{DS}=Drain-Source voltage

The height of the channel 104 at the drain end 112 is modeled to be the same as at the pinch-off point, H_{P}, as it is assumed that the channel 104 is uniform from the pinch-off point 114 to the drain end 112.

### Channel Length Models

The length of the channel 104 between the pinch-off point 114 and the drain end 112 is

$${L}_{2} = \frac{{V}_{DS} - {VDS}^{′}}{{E}_{L}} \qquad ( 18 )$$

where

$${E}_{L} = \sqrt{\frac{{qN}_{a} ( {V}_{DS} - {VDS}^{′} )}{2 {ɛɛ}_{O}}}$$

$${VDS}^{′} = {v}_{sat} {L}_{eff} / {μ}_{eff}$$

νₛₐₜ=Saturation velocity of charge carriers

The length of the channel 104 between the source end 110 and the pinch-off point 114 is accordingly

L₁=L_{eff}−L₂ (19)

### Thermal Conductance

The channel 104 has both a lateral thermal conductance and longitudinal thermal conductance. The substrate 306 is modeled as having a uniform background temperature T^{ref}. The lateral thermal conductance is taken relative to both the gate 106 above and a thermal reference in the substrate 306 below. These are combined into a single lateral conductance for a single, average reference temperature. When compared to the temperature of the substrate 306, which acts as a relatively distant reference temperature, the relatively small variation in the height of the channel 104 compared to the distance to the source of the reference temperature is negligible. Therefore, the variation of thermal conductance along the height of the channel 104 is modeled as being negligible. The lateral thermal conductance (G^{lat}) is modeled as being uniform along the length of the channel 104. In alternative embodiments, for complex MOSFET structures a uniform, effective lateral thermal conductivity can be calibrated from detailed 2D or 3D thermal conduction simulations.

The longitudinal thermal conductance (G^{long}) varies along the length of the channel 104 with the channel 104's cross-sectional area. The average longitudinal thermal conductance is

$${G}_{avg}^{long} = \frac{1}{{L}_{eff}} {\int }_{0}^{Leff} G ( x ) d x \qquad ( 20 )$$

where L_{eff} is the effective channel length.

The longitudinal thermal conductance along the channel 104's length is

G^{long}(x)=G_{O}e^{γx} (21)

where

$$γ = - \frac{1}{{L}_{eff}} ln [ \frac{{G}_{O}}{{G}_{L}} ]$$

G_{O}=Thermal conductance per unit length at the source end 110 (i.e. when x=0 [symbol] G^{long}(x=0)=G_{O}).

G_{L}=Thermal conductance per unit length at the drain end 112 (i.e. when x=L [symbol] G^{long}(x=L)=G_{L})

and where

$${G}_{avg}^{long} = \frac{{G}_{O}}{γ {L}_{eff}} [ {e}^{γ {L}_{eff}} - 1 ] \qquad ( 22 )$$

If λ is the thermal conductivity of channel, then

$${G}_{O} = \frac{{H}_{O} {W}_{eff}}{λ} and {G}_{L} = \frac{{H}_{P} {W}_{eff}}{λ} .$$

### Solution of the Heat Equation

The heat equation, Equation 1, is solved for both Subregions 1 and 2 below.

### Subregion 1: Non-Uniform Cross-Sectional Area

FIG. 5 shows Subregion 1 of the channel. For a differential length Δx of the channel:

$$φ ( x ) Δ x = {I}_{DS}^{2} R ( x ) Δ x$$

$$R ( x ) Δ x = \frac{ρΔ x}{{W}_{eff} {H}_{O}} {e}^{α x}$$

where I_{DS} is the drain current. The heat flux can be written as

$$F ( x ) = {G}_{avg}^{long} \frac{\partial T ( x )}{\partial x}$$

$$F ( x + Δ x ) = {G}_{avg}^{long} \frac{\partial T ( x + Δ x )}{\partial x}$$

$$f ( x ) = {G}^{lat} ( T ( x ) - {T}^{ref} )$$

In the limit when Δx→0, the heat equation takes the form of a 2nd order non-homogeneous differential equation:

$${G}_{avg}^{long} \frac{{d}^{2} T}{d {x}^{2}} - {G}^{lat} ( T ( x ) - {T}^{ref} ) + \frac{{I}_{DS}^{2} ρ}{{W}_{eff} {H}_{O}} {e}^{α x} = 0 \qquad ( 23 )$$

If the temperature function for Subregion 1 is T₁(x), Equation 23 can be written as

$${G}_{avg}^{long} \frac{{d}^{2} {T}_{1}}{d {x}_{1}^{2}} - {G}^{lat} ( {T}_{1} ( {x}_{1} ) - {T}^{ref} ) + \frac{{I}_{DS}^{2} ρ}{{W}_{eff} {H}_{O}} {e}^{α {x}_{1}} = 0 \qquad ( 24 )$$

The solution of non-homogeneous differential Equation 24 can be written as

$${T}_{1} ( {x}_{1} ) = {C}_{1} {e}^{{ξ}_{1} {x}_{1}} + {C}_{2} {e}^{- {ξ}_{1} {x}_{1}} + {T}^{ref} - \frac{{Ψ}^{2}}{{α}^{2} - {ξ}_{1}^{2}} {e}^{α {x}_{1}} \\ where \\ {ξ}_{1} = \sqrt{\frac{{G}^{lat}}{{G}_{avg}^{long}}} \\ Ψ = \sqrt{\frac{{I}_{sat}^{2} ρ}{{W}_{eff} {H}_{O} {G}_{avg}^{long}}} \\ {K}_{1} = \frac{{Ψ}^{2}}{{α}^{2} - {ξ}_{1}^{2}} \qquad ( 25 )$$

C₁ and C₂ are constants whose values are determined below.

### Subregion 2: Uniform Cross-Sectional Area

FIG. 6 shows Subregion 2 of the channel 104. The total resistance in Subregion 2 is denoted as R₂.

For a differential length Δx of the channel 104:

$$φ ( x ) Δ x = {I}_{DS}^{2} ( \frac{{R}_{2}}{{L}_{2}} ) Δ x$$

The heat flux can be written as

$$F ( x ) = {G}_{avg}^{long} \frac{\partial T ( x )}{\partial x}$$

$$F ( x + Δ x ) = {G}_{avg}^{long} \frac{\partial T ( x + Δ x )}{\partial x}$$

$$f ( x ) = {G}^{lat} ( T ( x ) - {T}^{ref} )$$

In the limit when Δx→0, the heat equation takes the form of the following second-order non-homogeneous differential equation:

$${G}_{avg}^{long} \frac{{d}^{2} T}{d {x}^{2}} - {G}^{lat} ( T ( x ) - {T}^{ref} ) + {I}_{DS}^{2} {R}_{2} = 0 \qquad ( 26 )$$

If the temperature function of Subregion 2 is T₂(x), then Equation 26 can be written as

$${G}_{avg}^{long} \frac{{d}^{2} {T}_{2}}{d {x}_{2}^{2}} - {G}^{lat} ( {T}_{2} ( {x}_{2} ) - {T}^{ref} ) + {I}_{DS}^{2} {R}_{2} = 0 \qquad ( 27 )$$

The solution of Equation 27 can be written as

$${T}_{2} ( {x}_{2} ) = {D}_{1} {e}^{{ξ}_{2} {x}_{2}} + {D}_{2} {e}^{- {ξ}_{2} {x}_{2}} + \frac{β}{{ξ}_{2}^{2}} \\ where \\ {ξ}_{2} = \sqrt{\frac{{G}_{2}^{lat}}{{G}_{avg}^{long}}} \\ β = - \frac{{G}_{2}^{lat}}{{G}_{avg}^{long}} {T}^{ref} - \frac{{I}_{DS}^{2}}{{G}_{avg}^{long}} {R}_{2} \\ {K}_{2} = \frac{β}{{ξ}_{2}^{2}} \qquad ( 28 )$$

D₁ and D₂ are constants whose values are determined using the boundary conditions, below.

### Boundary Conditions and Complete Solution

The temperatures of the source and drain ends 110,112 of the channel 104 are determined by boundary conditions. If the temperature at the source end 110 is T_{O} and at the drain end is T_{L}, then the two boundary conditions can be written as

T₁(x₁)|ₓ_{₁}₌₀=T_{O} (29)

T₂(x₂)|ₓ_{₂}_{=L}_{₂}=T_{L} (30)

The temperature at the pinch-off point 114 as determined by Equation 25 is the same as determined by Equation 28. Additionally, the heat flux leaving Subregion 1 enters Subregion 2. These facts provide two more boundary conditions:

$$\begin{matrix}{T}_{1} ( {x}_{1} ) {\vert}_{{x}_{1} = {L}_{1}} = {T}_{2} ( {x}_{2} ) {\vert}_{{x}_{2} = 0} & ( 31 ) \\ {G}_{avg}^{long} \frac{d {T}_{1}}{d {x}_{1}} {\vert}_{{x}_{1} = {L}_{1}} = {G}_{avg}^{long} \frac{d {T}_{2}}{d {x}_{2}} {\vert}_{{x}_{2} = 0} & ( 32 )\end{matrix}$$

Using Equations 25, 28, 29, 30, 31, and 32, the unknown coefficients, C₁, C₂, D₁, and D₂ can be calculated as:

$$\begin{matrix} {T}_{O} = {C}_{1} + {C}_{2} + {T}^{ref} - \frac{{Ψ}^{2}}{{α}^{2} - {ξ}_{1}^{2}} & ( 33 ) \\ {T}_{L} = {D}_{1} {e}^{{ξ}_{2} {L}_{2}} + {D}_{2} {e}^{- {ξ}_{2} {L}_{2}} + \frac{β}{{ξ}_{2}^{2}} & ( 34 ) \\ {C}_{1} {e}^{{ξ}_{1} {L}_{1}} + {C}_{2} {e}^{- {ξ}_{1} {L}_{1}} + {T}^{ref} - \frac{{Ψ}^{2}}{{α}^{2} - {ξ}_{1}^{2}} = {D}_{1} + {D}_{2} + \frac{β}{{ξ}_{2}^{2}} & ( 35 ) \\ {G}_{avg}^{long} ( {C}_{1} {ξ}_{1} {e}^{{ξ}_{1} {L}_{1}} - {C}_{2} {ξ}_{1} {e}^{- {ξ}_{1} {L}_{1}} - α \frac{{Ψ}^{2}}{{α}^{2} - {ξ}_{1}^{2}} {e}^{α {L}_{1}} ) = {G}_{avg}^{Long} ( {D}_{1} {ξ}_{2} - {D}_{2} {ξ}_{1} ) & ( 36 ) \\ {C}_{1} = {C}_{1}^{′} - {C}_{1}^{″} & ( 37 ) \\ {D}_{1} = {D}_{1}^{′} - {D}_{1}^{″} \\ where & ( 38 ) \\ {C}_{1}^{′} = \frac{( {ξ}_{2} + {ξ}_{2} {e}^{2 {ξ}_{2} {L}_{2}} )}{\begin{matrix}( {e}^{{ξ}_{1} {L}_{1}} - {e}^{- {ξ}_{1} {L}_{1}} ) ( 1 + {e}^{2 {ξ}_{2} {L}_{2}} ) {ξ}_{2} - \\ ( {e}^{{ξ}_{1} {L}_{1}} + {e}^{- {ξ}_{1} {L}_{1}} ) ( 1 - {e}^{2 {ξ}_{2} {L}_{2}} )\end{matrix}} \times \{ \begin{matrix}{T}_{L} {e}^{{ξ}_{2} {L}_{2}} - ( {T}_{O} - {T}^{ref} ) {e}^{- {ξ}_{1} {L}_{1}} - {T}^{ref} + \\ \frac{{Ψ}^{2}}{{α}^{2} - {ξ}_{1}^{2}} ( {e}^{{ξ}_{1} {L}_{1}} - {e}^{- {ξ}_{1} {L}_{1}} ) + \frac{β}{{ξ}_{2}^{2}} ( 1 - {e}^{{ξ}_{2} {L}_{2}} )\end{matrix} \} & \\ {D}_{1}^{′} = \frac{( {e}^{{ξ}_{1} {L}_{1}} + {e}^{- {ξ}_{1} {L}_{1}} )}{\begin{matrix}( {e}^{{ξ}_{1} {L}_{1}} - {e}^{- {ξ}_{1} {L}_{1}} ) ( 1 + {e}^{2 {ξ}_{2} {L}_{2}} ) {ξ}_{2} - \\ ( {e}^{{ξ}_{1} {L}_{1}} + {e}^{- {ξ}_{1} {L}_{1}} ) ( 1 - {e}^{2 {ξ}_{2} {L}_{2}} )\end{matrix}} \times \{ \begin{matrix}{T}_{L} {e}^{{ξ}_{2} {L}_{2}} - ( {T}_{O} - {T}^{ref} ) {e}^{- {ξ}_{1} {L}_{1}} - {T}^{ref} + \\ \frac{{Ψ}^{2}}{{α}^{2} - {ξ}_{1}^{2}} ( {e}^{{ξ}_{1} {L}_{1}} - {e}^{- {ξ}_{1} {L}_{1}} ) + \frac{β}{{ξ}_{2}^{2}} ( 1 - {e}^{{ξ}_{2} {L}_{2}} )\end{matrix} \} & \\ {C}_{1}^{″} = \frac{( 1 - {e}^{2 {ξ}_{1} {L}_{1}} )}{\begin{matrix}( {e}^{{ξ}_{1} {L}_{1}} - {e}^{- {ξ}_{1} {L}_{1}} ) ( 1 + {e}^{2 {ξ}_{2} {L}_{2}} ) {ξ}_{2} - \\ ( {e}^{{ξ}_{1} {L}_{1}} + {e}^{- {ξ}_{1} {L}_{1}} ) ( 1 - {e}^{2 {ξ}_{2} {L}_{2}} )\end{matrix}} \times \{ \begin{matrix}( {T}_{O} - {T}^{ref} ) {ξ}_{1} {e}^{- {ξ}_{1} {L}_{1}} - {T}_{L} {e}^{{ξ}_{2} {L}_{2}} {ξ}_{2} + \\ \frac{{Ψ}^{2}}{{α}^{2} - {ξ}_{1}^{2}} ( {αe}^{α {L}_{1}} + {ξ}_{1} {e}^{- α {L}_{1}} ) + \frac{β}{{ξ}_{2}^{2}} {ξ}_{2} {e}^{{ξ}_{2} {L}_{2}}\end{matrix} \} & \\ {D}_{1}^{″} = \frac{( {e}^{{ξ}_{1} {L}_{1}} + {e}^{- {ξ}_{1} {L}_{1}} )}{\begin{matrix}( {e}^{{ξ}_{1} {L}_{1}} - {e}^{- {ξ}_{1} {L}_{1}} ) ( 1 + {e}^{2 {ξ}_{2} {L}_{2}} ) {ξ}_{2} - \\ ( {e}^{{ξ}_{1} {L}_{1}} + {e}^{- {ξ}_{1} {L}_{1}} ) ( 1 - {e}^{2 {ξ}_{2} {L}_{2}} )\end{matrix}} \times \{ \begin{matrix}( {T}_{O} - {T}^{ref} ) {ξ}_{1} {e}^{- {ξ}_{1} {L}_{1}} - {T}_{L} {e}^{{ξ}_{2} {L}_{2}} {ξ}_{2} + \\ \frac{{Ψ}^{2}}{{α}^{2} - {ξ}_{1}^{2}} ( {αe}^{α {L}_{1}} + {ξ}_{1} {e}^{- α {L}_{1}} ) + \frac{β}{{ξ}_{2}^{2}} {ξ}_{2} {e}^{{ξ}_{2} {L}_{2}}\end{matrix} \} & \\ {C}_{2} = {T}_{O} - {C}_{1} - {T}^{ref} + \frac{{Ψ}^{2}}{{α}^{2} - {ξ}_{1}^{2}} & \\ {D}_{2} = {T}_{L} {e}^{{ξ}_{2} {L}_{2}} - {D}_{1} {e}^{2 {ξ}_{2} {L}_{2}} - \frac{β}{{ξ}_{2}^{2}} {e}^{{ξ}_{2} {L}_{2}} & \end{matrix}$$

The temperature of the channel 104 along its length from the source end 110 to the drain end 112 can be written as

$$\begin{matrix}T ( x ) = \{ \begin{matrix}{T}_{1} ( {x}_{1} ) , & 0 \leq {x}_{1} \leq {L}_{1} for 0 \leq x \leq {L}_{1} \\ {T}_{2} ( {x}_{2} ) , & 0 \leq {x}_{2} \leq {L}_{2} for {L}_{1} \leq x \leq L\end{matrix} \\ where & ( 39 ) \\ L = {L}_{1} + {L}_{2} & ( 40 )\end{matrix}$$

### The Channel Temperature at Pinch-Off

The channel temperature at the pinch-off point 114 T_{pinch} is given as T_{pinch}=T₁(x₁)|x_{₁}_{=L}_{₁}.

### M-Network Representation of the Channel 104

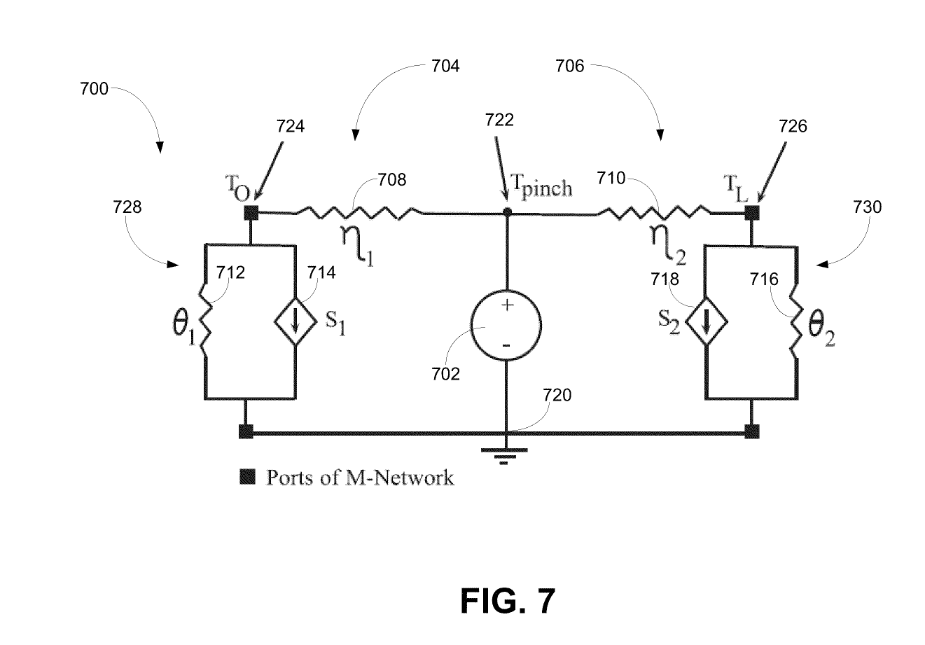

The foregoing analysis is used to model steady-state (DC) temperature within the channel 104 of the MOSFET 100 using an electric circuit 700 as shown in FIG. 7 (“M-Network 700”). Each of the nodes of the M-Network 700 corresponds to a location within the MOSFET 100, and the voltage at one of the nodes of the M-Network 700 represents the temperature at the corresponding location in the MOSFET 100. In this sense, the M-Network 700 is an electrical circuit that is equivalent to the steady-state thermal conditions of the channel 104.

The M-Network 700 includes a voltage source 702 that is connected between a common node 720 that corresponds to the MOSFET 100's substrate 306 and a pinch-off node 722 that corresponds to the pinch-off point 114. The M-Network 700 also includes a source branch 704 that corresponds to the portion of the channel 104 between the source end 110 and the pinch-off point 114 (Subregion 1), and a drain branch 706 that corresponds to the portion of the channel 104 between the drain end 112 and the pinch-off point 114 (Subregion 2). The pinch-off node 722 acts as a dividing node that divides the source and drain branches 704,706 from each other, which are the branches of the circuit that model the two subregions of the channel 104.

Each of the source and drain branches 704,706 is connected in parallel between the pinch-off node 722 and the common node 720. Each of the source and drain branches 704,706 includes a first resistor 708,710 that has one end connected to the pinch-off node 722, and a parallel branch 728,730 that includes a current source 714,718 and a second resistor 712,716 connected together in parallel. In each of the source and drain branches 704,706, the parallel branch 728,730 is connected in series with the first resistor 708,710, and the parallel branch 728,730 and the first resistor 708,710 connect the pinch-off node 722 to the common node 720. The first resistor 708 in the source branch 704 has a conductance of η₁, the second resistor 712 in the parallel branch 728 of the source branch 704 (“source parallel branch 728”) has a conductance of θ₁, and the current source 714 in the source parallel branch 728 has a magnitude of S₁. Similarly, the first resistor 710 in the drain branch 706 has a conductance of η₂, the second resistor 716 in the parallel branch 730 of the drain branch 706 (“drain parallel branch 730”) has a conductance of θ₂, and the current source 718 in the drain parallel branch 730 has a magnitude of S₂. A voltage source of magnitude T_{pinch} is connected between the common node 720 and the pinch-off node 722; the magnitude of T_{pinch} corresponds to the temperature of the pinch-off point. The node 724 between the source parallel branch 728 and the first resistor 708 of the source branch 704 corresponds to the source end 110 of the channel 104 (“source end node 724”), and the voltage T_{O} at this node 724 represents the temperature at the source end 110. Similarly, the node 726 between the drain parallel branch 730 and the first resistor 710 of the drain branch 706 corresponds to the drain end 112 of the channel 104 (“drain end node 726”), and the voltage T_{L}, at this node 726 represents the temperature at the drain end 112. F_{O} represents the current at the source end node 724, and F_{L} represents the current at the drain end node 726. The source end and drain end nodes 724,726 are the ports of the M-Network 700. The conductances θ₁,θ₂ of the resistors 712,716 in the source and drain parallel branches 728,730 represent a thermal conduction path to ground.

F_{O} and F_{L} are given by

$$\begin{matrix}{F}_{O} = {G}_{avg}^{long} \frac{d {T}_{1}}{d x} \vert x = 0 & ( 41 ) \\ {F}_{L} = {G}_{avg}^{long} \frac{d {T}_{2}}{d x} \vert x = {L}_{2} & ( 42 )\end{matrix}$$

The requirement for conservation of flux (in electric circuit analysis known as Kirchoff's current law) results in the following equations:

F_{O}=η₁T_{pinch}−(η₁+θ₁)T_{O}−S₁ (43)

F_{L}=(η₂+θ₂)T_{L}−η₂T_{pinch}+S₂ (44)

where

T_{pinch}=C₁e^{ξ}^{₁}^{L}^{₁}+C₂e^{-ξ}^{₁}^{L}^{₁}+T^{ref}−K₁e^{α}^{₁}^{L}^{₁}

Equations 41 and 42 can be solved and compared with Equations 43 and 44 to find out the values of η₁, η₂, θ₁, θ₂, and S₂:

$${η}_{1} = {G}_{avg}^{long} 2 {ξ}_{1}$$

$${θ}_{1} = {G}_{avg}^{long} \frac{4 {ξ}_{1} {ξ}_{2}}{M} {e}^{- {ξ}_{1} {L}_{1}} + {G}_{avg}^{long} {ξ}_{1} - {η}_{1} \{ \frac{2 {ξ}_{2} {e}^{- {ξ}_{1} {L}_{1}}}{M} + 1 \} + {e}^{- {ξ}_{1} {L}_{1}}$$

$${S}_{1} = {G}_{avg}^{long} \{ \frac{2 {ξ}_{1}}{M} {γ}_{1} - {K}_{1} ( {α}_{1} + {ξ}_{1} ) \} - {T}^{ref} {ξ}_{1} - \frac{{η}_{1}}{M} \{ {e}^{{ξ}_{1} {L}_{1}} - {e}^{- {ξ}_{1} {L}_{1}} \} {γ}_{1} - {T}^{ref} {e}^{- {ξ}_{1} {L}_{1}} + {T}^{ref} + {K}_{1} \{ {e}^{- {ξ}_{1} {L}_{1}} - {e}^{{α}_{1} {L}_{1}} \}$$

$${η}_{2} = - \frac{{e}^{{ξ}_{1} {L}_{1}}}{( {e}^{{ξ}_{1} {L}_{1}} - {e}^{- {ξ}_{1} {L}_{1}} )} \{ \frac{M {e}^{- {ξ}_{1} {L}_{1}}}{2 {ξ}_{2}} + {G}_{avg}^{long} {e}^{{ξ}_{2} {L}_{2}} {e}^{- {ξ}_{1} {L}_{1}} [ ( {e}^{{ξ}_{1} {L}_{1}} + {e}^{- {ξ}_{1} {L}_{1}} ) + {ξ}_{1} ( {e}^{{ξ}_{1} {L}_{1}} - {e}^{- {ξ}_{1} {L}_{1}} ) ] \}$$

$${θ}_{2} = {η}_{2} \{ \frac{2 {ξ}_{2} {e}^{{ξ}_{2} {L}_{2}} ( {e}^{{ξ}_{1} {L}_{1}} - {e}^{- {ξ}_{1} {L}_{1}} )}{M} - 1 \} - {G}_{avg}^{long} \{ \frac{2 {ξ}_{2}}{M} {e}^{2 {ξ}_{2} {L}_{2}} [ ( {e}^{{ξ}_{1} {L}_{1}} + {e}^{- {ξ}_{1} {L}_{1}} ) + {ξ}_{2} ( {e}^{{ξ}_{1} {L}_{1}} - {e}^{- {ξ}_{1} {L}_{1}} ) ] - {ξ}_{2} \}$$

$${S}_{2} = {G}_{avg}^{long} \{ {ξ}_{2} {K}_{2} + \frac{2 {ξ}_{2} {e}^{{ξ}_{2} {L}_{2}}}{M} {γ}_{2} \} + {T}^{ref} \{ {e}^{- {ξ}_{1} {L}_{1}} - 1 \} - {K}_{1} \{ {e}^{- {ξ}_{1} {L}_{1}} - {e}^{{α}_{1} {L}_{1}} \} - \frac{{η}_{2}}{M} \{ {e}^{{ξ}_{1} {L}_{1}} - {e}^{- {ξ}_{1} {L}_{1}} \} {γ}_{1}$$

$$where$$

$$M = ( {e}^{{ξ}_{1} {L}_{1}} - {e}^{- {ξ}_{1} {L}_{1}} ) ( 1 + {e}^{2 {ξ}_{2} {L}_{2}} ) {ξ}_{2} - ( {e}^{{ξ}_{1} {L}_{1}} + {e}^{- {ξ}_{1} {L}_{1}} ) ( 1 - {e}^{2 {ξ}_{2} {L}_{2}} )$$

$${γ}_{1} = {ξ}_{2} ( 1 + {e}^{2 {ξ}_{2} {L}_{2}} ) \{ - {T}^{ref} ( {e}^{- {ξ}_{1} {L}_{1}} + 1 ) + {K}_{1} ( {e}^{{α}_{1} {L}_{1}} - {e}^{- {ξ}_{1} {L}_{1}} ) + {K}_{2} ( 1 - {e}^{{ξ}_{2} {L}_{2}} ) \} + ( 1 - {e}^{2 {ξ}_{2} {L}_{2}} ) \{ - {T}^{ref} {ξ}_{1} {e}^{- {ξ}_{1} {L}_{1}} + {K}_{1} ( {α}_{1} {e}^{{α}_{1} {L}_{1}} + {ξ}_{1} {e}^{- {ξ}_{1} {L}_{1}} ) + {K}_{2} {ξ}_{2} {e}^{{ξ}_{2} {L}_{2}} \}$$

$${γ}_{2} = {T}^{ref} \{ ( {e}^{- {ξ}_{1} {L}_{1}} - 1 ) ( {e}^{{ξ}_{1} {L}_{1}} + {e}^{- {ξ}_{1} {L}_{1}} ) + {ξ}_{1} {e}^{- {ξ}_{1} {L}_{1}} ( {e}^{{ξ}_{1} {L}_{1}} - {e}^{- {ξ}_{1} {L}_{1}} ) \} + {K}_{1} \{ ( {e}^{{α}_{1} {L}_{1}} - {e}^{- {ξ}_{1} {L}_{1}} ) ( {e}^{{ξ}_{1} {L}_{1}} + {e}^{- {ξ}_{1} {L}_{1}} ) - ( {α}_{1} {e}^{{α}_{1} {L}_{1}} + {ξ}_{1} {e}^{- {ξ}_{1} {L}_{1}} ) + ( {e}^{{ξ}_{1} {L}_{1}} - {e}^{- {ξ}_{1} {L}_{1}} ) \} + {K}_{2} \{ ( 1 - {e}^{{ξ}_{2} {L}_{2}} ) ( {e}^{{ξ}_{1} {L}_{1}} + {e}^{- {ξ}_{1} {L}_{1}} ) - {ξ}_{2} {e}^{{ξ}_{2} {L}_{2}} ( {e}^{{ξ}_{1} {L}_{1}} - {e}^{- {ξ}_{1} {L}_{1}} ) \}$$

The heat equation can accordingly be analytically solved for the MOSFET 100, and the channel 104's temperature profile can be estimated. Physical device parameters are extracted from BSIM3 models; MOSFET geometry information is read from an extracted circuit layout in the SPICE format; saturation current and other variables for the M-Network 700 are determined; and then voltage at the nodes of the M-Network 700 are determined to determine the temperature at the locations within the MOSFET that correspond to those nodes. Subsequently, and in another embodiment, the temperature at any location within the channel can be analytically determined using Equations 25 and 28.

### Integration in the VLSI CAD Flow

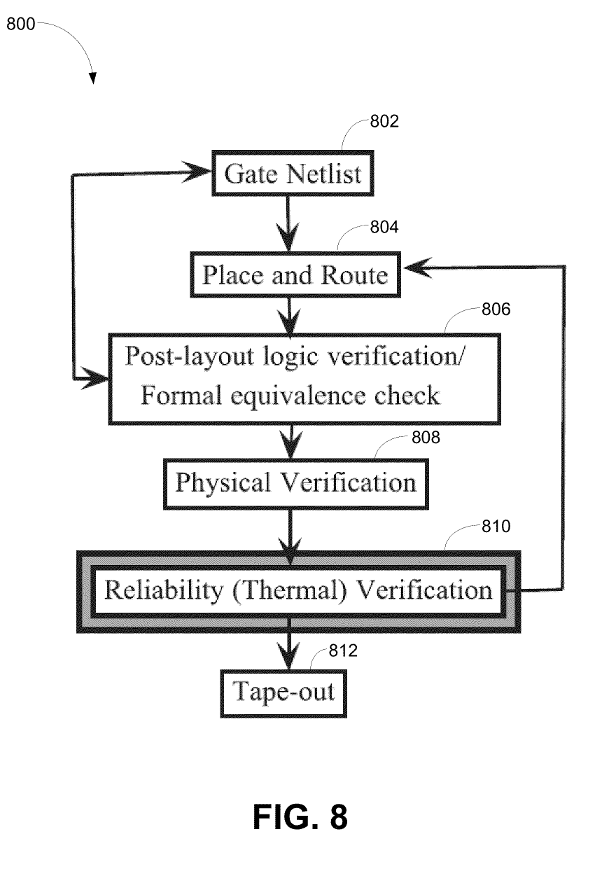

FIG. 8 shows a post-logic synthesis VLSI (Very-large-scale Integration) CAD (Computer-aided Design) flow 800. At block 802, the netlist is generated; at block 804, placing and routing (layout) is performed; at block 806, post-layout logic verification and a formal equivalence check are performed; at block 808, physical verification is performed; and at block 810, prior to tape-out, thermal reliability verification is performed in accordance with the foregoing disclosure. If a problem is discovered during thermal verification, the layout of the IC can be changed at block 804, and blocks 806 to 810 can be repeated. Once the IC passes thermal verification, tape-out is performed at block 812.

### Verification

The foregoing describes solving the heat equation analytically. For a comparative analysis of the results of the method of the present disclosure versus a conventional method, the heat equation for both Subregions 1 and 2 of the channel 104 are solved using a conventional finite difference approach, below, and the results are compared to those determined analytically. The finite difference approach is based on Taylor's approximation for 2nd order derivatives given by:

$$\frac{f ( x - h ) - 2 f ( x ) + f ( x + h )}{{h}^{2}} = {f}^{″} ( x ) + \frac{{f}^{( 4 )} ( v )}{12} {h}^{2} \qquad ( 45 )$$

where, h is a small interval and ƒ″(x) is the second derivative of function ƒ(x). The second term on the right hand side of Equation 45 is the remainder term and is treated as approximation error.

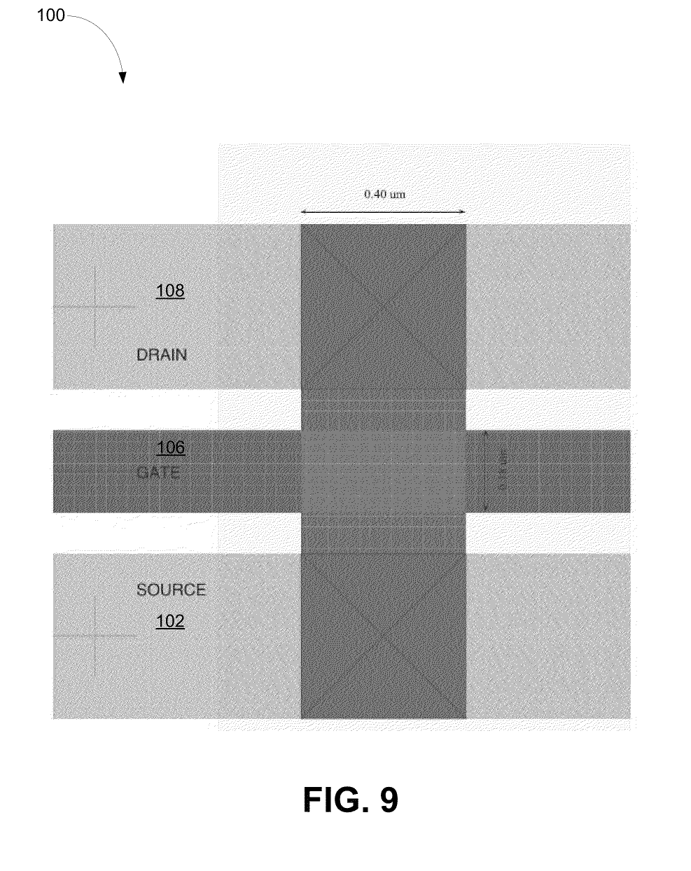

Below, thermal simulations on an n-type MOSFET 100 are performed using analytical and finite difference approaches. FIG. 9 shows the layout of the MOSFET 100; the MOSFET 100 has a drawn length of 0.18 μm and a drawn width of 0.40 μm. The full SPICE BSIM3 model for the device is given below in Table 1, while Table 2 lists non-BSIM3 parameters used in the simulations:

TABLE 1
BSIM3 Parameters used in Simulations

| Parameter | Description | Value | Unit |
|---|---|---|---|
| Vₜₕ₀ | Threshold voltage | 0.3696386 | V |
| m₀ | Mobility | 670.0 | cm²/Vs |
| vₛₐₜ | Saturation velocity | 86301.58 | m/s |
| Wₗ | Coefficient of length | 0.0 | m^{Wln} |
| | dependence for width offset | | |
| Wₗₙ | Power of length dependence | 0.0 | none |
| | for width offset | | |
| W_{wn} | Power of width dependence | 1.0 | none |
| | for width offset | | |
| W_{w} | Width dependence for width | 0.0 | m^{Wwn} |
| | offset | | |
| W_{wl} | Length and width cross term | 0.0 | m^{Wwn +} ^{Wln} |
| | for width offset | | |
| Lₗ | Length dependence for length | 0.0 | m^{Lln} |
| | offset | | |
| Lₗₙ | Length dependence for length | 1.0 | none |
| | offset | | |
| L_{w} | Width dependence for length | 0.0 | m^{Lwn} |
| | offset | | |
| L_{wn} | Width dependence for length | 0.0 | none |
| | offset | | |
| L_{wl} | Length and width cross term | 0.0 | m^{Lwn +} ^{Lln} |
| | for length offset | | |
| Lᵢₙₜ | Length offset fitting | 1.69494e−8 | m |
| | parameter | | |
| Tₒₓ | Gate oxide thickness | 1.5e−8 | m |
| N_{sub} | Substrate doping | 6.0e16 | cm⁻³ |
| | concentration | | |

TABLE 2
Other Parameters Used in Simulations

| Parameter | Description | Value | Unit |
|---|---|---|---|
| k | Boltzmann constant | 1.38 × 10⁻²³ | m²kgs⁻²K⁻¹ |
| εᵣ | Oxide dielectric constant | 3.9 | none |
| εₒ | Permittivity of air | 8.85 × 10⁻¹² | F/m |

### Test Scenario Using Externally Supplied Drain Current

In this test scenario, the temperature of the channel is determined while the MOSFET is subject to an externally supplied current. In this test, a current of 2 mA is supplied externally by a designer, the layout drawn length of the MOSFET is 0.28 μm, the width is 0.40 μm, the applied gate voltage is 1.0 V, the drain voltage is 1.5 V, the source end temperature is set to 565 K, the drain end is set at 567 K, and the reference temperature is set to 456 K. Determined analytically, the average channel temperature is 586.19 K; the maximum channel temperature is 588.68 K at a distance of 0.2115 μm from the source end 110; and the temperature at the pinch-off point is 588.46 K at a distance of 0.2093 μm from the source end.

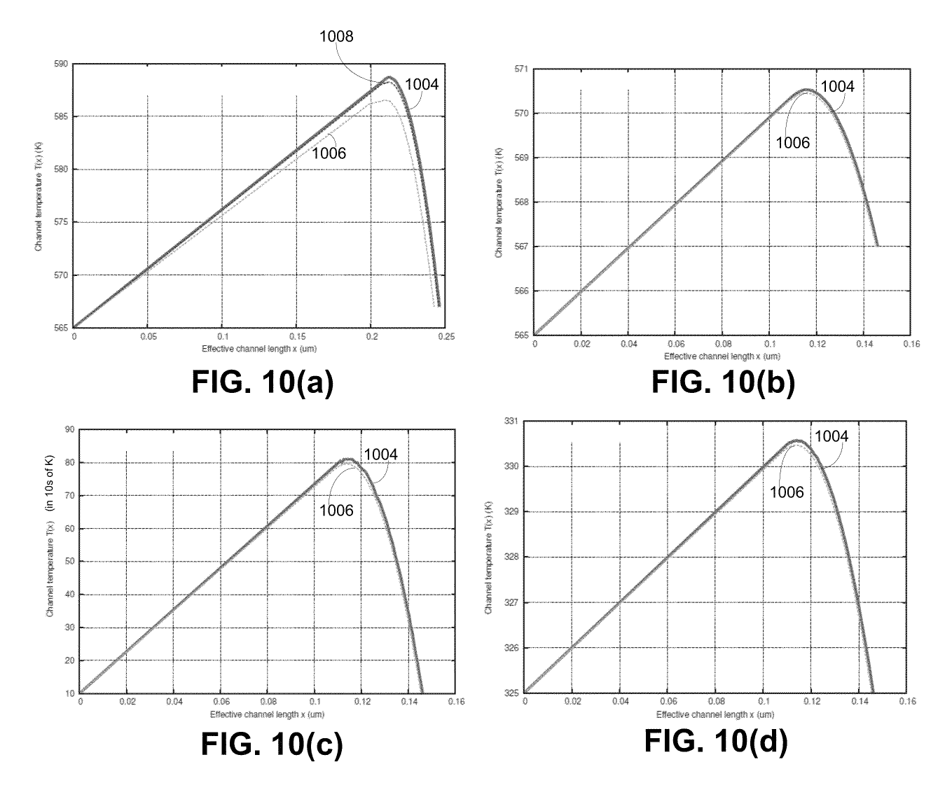

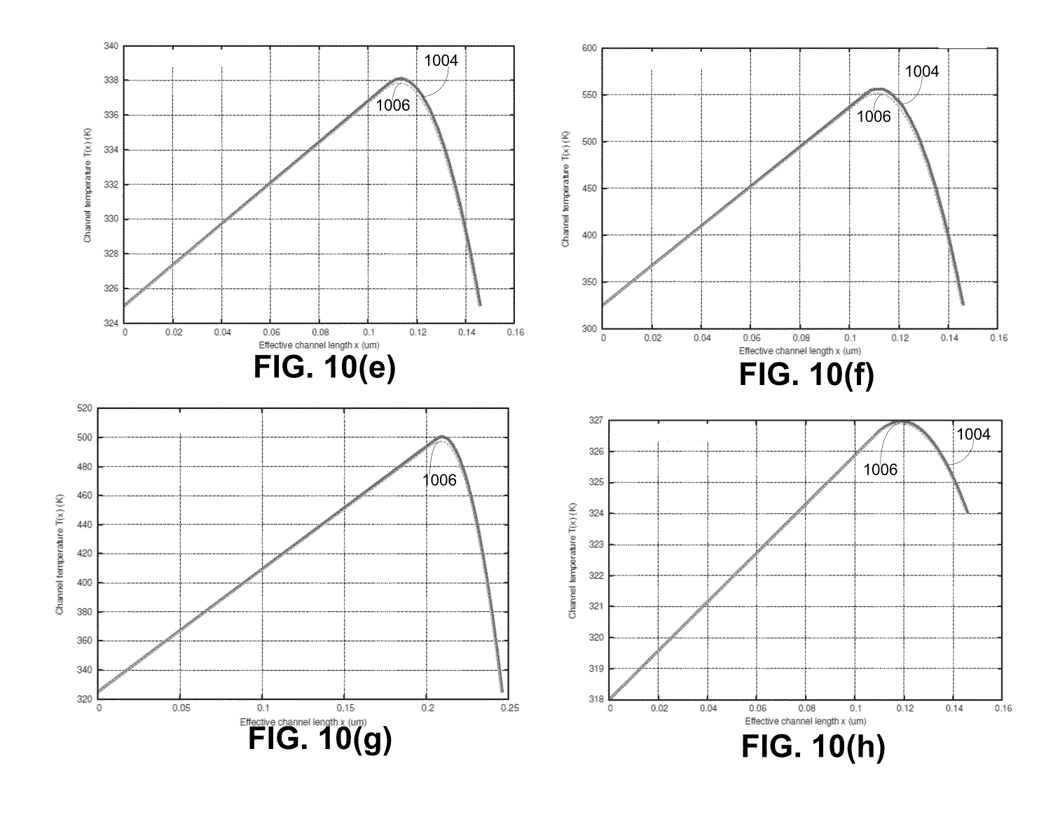

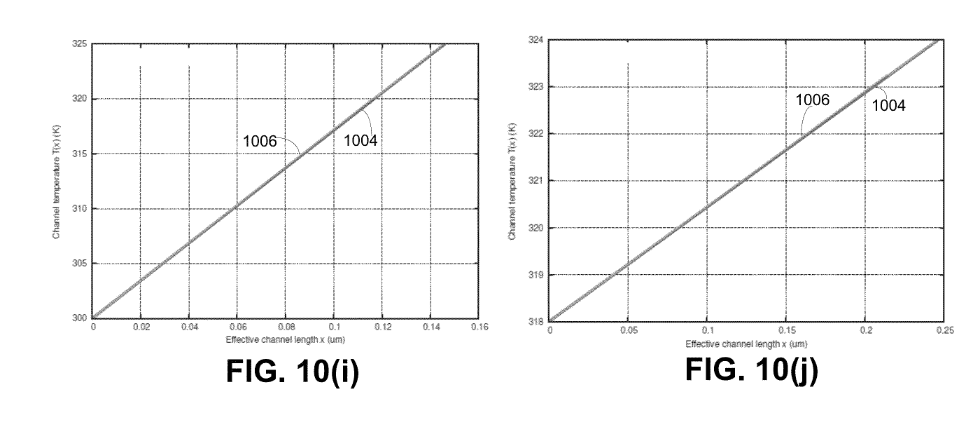

FIG. 10(a) graphs the analytical solution as a curve 1004 (“analytical curve 1004”) shown in solid lines, and graphs two different finite difference solutions as curves 1004,1006 (“finite difference curves 1004,1006”) shown in dashed lines. While there is a significant difference between the analytical curve 1004 and one of the finite difference curves 1006, when the step size used in the finite difference approach is reduced and its accuracy accordingly increased, the resulting finite difference curve 1004 more closely corresponds to the analytical curve 1004.

### Test Scenario for a Smaller MOSFET

In this test, the layout drawn length and width of the MOSFET are respectively 0.18 μm and 0.40 μm, and the gate and drain voltages are both 1.5 V. The source end temperature is 565 K, the drain end temperature is 567 K, and the reference temperature is 456 K. FIG. 10(b) shows both the analytical and finite difference results as the analytical curve 1004 and the finite difference curve 1006, respectively. Determined analytically, the maximum channel temperature is 570.52 K at a distance of 0.114 μm from the source end; the temperature at the pinch-off point is 570.36 K at a distance 0.109 μm along the length of the channel from the source end; and the saturation current is 0.269 mA.

Test Scenario for the Case when the Source, Drain, and the Reference Temperatures are Identical

In this test, the layout drawn length of the MOSFET is 0.18 μm and the width is 0.40 μm, the applied gate voltage is 1.5 V, the drain voltage is 1.5 V, and the source, drain, and reference temperatures all are set to 10 K. FIG. 10(c) shows both the analytical and finite difference results as the analytical curve 1004 and the finite difference curve 1006, respectively. The drain current is 0.2699 mA. Determined analytically, the average channel temperature is 5.05 K; the maximum channel temperature is 8.1 K at a distance of 0.1124 μm along the length of the channel from the source end; and the temperature at the pinch-off point is 7.95 K at a distance of 0.109 μm from the source end.

Below, test scenarios are described that compare the analytical and conventional finite difference approaches when the MOSFET operates in different modes.

### Saturation Mode of Operation

In the saturation mode, the MOSFET is on and it conducts current between the source and the drain. The MOSFET threshold voltage for the BSIM3 technology file used in this work is 0.39V. The value of λ is 0.20. The following tests are performed with the MOSFET in the saturation mode.

Test Scenario when Gate and Drain are at Same Voltage

In this test, the source and drain temperatures are set to 325 K respectively, and the reference temperature is set to 300 K. The applied gate voltage is 1.5 V and the drain voltage is 1.5 V. The layout drawn width of the MOSFET is 0.40 μm and the length is 0.18 μm. The saturation drain current is 0.2699 mA. FIG. 10(d) shows both the analytical and finite difference results as the analytical curve 1004 and the finite difference curve 1006, respectively. Determined analytically, the maximum channel temperature is 330.57 K at a distance of 0.113 μM from the source end; and the temperature at the pinch-off point is 330.46 K at a distance 0.109 μm along the length of the channel from the source end.

### Test Scenario for the Case of Different Gate and Drain Voltages

In this test, the source and the drain end temperatures are set to 325 K respectively, and the reference temperature is set to 300 K. The applied gate voltage is 1.8 V and the drain voltage is 2.2 V. The layout drawn width of MOSFET is 0.40 μm and the length is 0.18 μm. The saturation drain current is 0.4322 mA. FIG. 10(e) shows both the analytical and finite difference results as the analytical curve 1004 and the finite difference curve 1006, respectively. Determined analytically, the maximum channel temperature is 338.12 K at a distance 0.1137 μm from the source end; and the temperature at the pinch-off point is 337.81 K at a distance 0.108 μm from the source end.

### Test Scenario for The Case of High Gate and Drain Voltages

In this test, source and drain temperatures are set to 325 K respectively, and the reference temperature is set to 300 K. The applied gate and drain voltages are both 5.0 V. The layout drawn width of the MOSFET is 0.18 μm and the length is 0.40 The saturation drain current to be 4.52 mA. FIG. 10(f) shows both the analytical and finite difference results as the analytical curve 1004 and the finite difference curve 1006, respectively. Determined analytically, the average channel temperature for this case is 460.66 K; the maximum channel temperature is 556.00 K at a distance 0.1102 μm from the source end; and the temperature at the pinch-off point is 550.26 K at a distance 0.10631 μm from the source end.

Test Scenario for a Large MOSFET Device with High Drain Current

In this test, the source and the drain end temperatures are set to 325 K respectively, and the reference temperature is set to 300 K. The applied gate and drain voltages are both 5.0 V. The layout drawn width of the MOSFET is 0.40 μm and the length is 0.28 μm. The saturation drain current is 2.689 mA. FIG. 10(g) shows both the analytical and finite difference results as the analytical curve 1004 and the finite difference curve 1006, respectively. Determined analytically, the average channel temperature for this case is 429.03 K; the maximum temperature is 500.50 K at a distance 0.208 μm from the source end; and the temperature at the pinch-off point is 499.17 K at a distance 0.206 μm from the source end.

### Test Scenario for Different Source/Drain Temperatures and Voltages

In this test, the source end temperature is set to 318 K, the drain end temperature is set to 324 K, and the reference temperature is set to 298 K. The applied gate voltage is 1.2 V and the drain voltage is 1.8 V. The layout drawn width of the MOSFET is 0.40 μm and the length is 0.18 μm. The saturation drain current is 0.145 mA. FIG. 10(h) shows both the analytical and finite difference results as the analytical curve 1004 and the finite difference curve 1006, respectively. Determined analytically, the maximum temperature is 326.97 K at a distance of 0.118 μm from the source end; and the temperature at the pinch-off point is 326.58 K at a distance of 0.109 μm from the source end.

### Linear/Ohmic Mode of Operation

When the MOSFET operates in the linear mode, the drain current increases linearly with the drain voltage. Under these conditions the MOSFET behaves as a voltage dependent resistor whose resistance is determined by the gate voltage. The current and the voltage follow the ohmic relationship in this mode of operation. The following tests are performed with the MOSFET in the linear mode.

### Test Scenario for the Case of Different Temperatures at the Source and the Drain

In this test, the source end temperature is set to 300 K, the drain end temperature is set to 325 K, and the reference temperature has been set to 300 K. The applied gate voltage is 1.5 V and the drain voltage is 1.0 V. The layout drawn width of MOSFET is 0.40 μm and the length is 0.18 μm. Linear mode drain current is determined to be 0.0245 mA. FIG. 10(i) shows both the analytical and finite difference results as the analytical curve 1004 and the finite difference curve 1006, respectively. Determined analytically, the maximum channel temperature is 325 K at a distance of 0.146 μm from the source end; and the temperature at the pinch-off point is 318.97 K at a distance of 0.110 μm from the source end.

### Test Scenario for a Larger Device in the Ohmic Operating Subregion

In this test, the source end temperature is set to 318 K, the drain end temperature is set to 324 K, and the reference temperature is set to 300 K. The applied gate voltage is 1.0 V and the drain voltage is 0.1 V. The layout drawn width of the MOSFET is 0.40 μm and the length is 0.28 μm. A drain current of 0.01455 mA is determined. FIG. 10(j) shows both the analytical and finite difference results as the analytical curve 1004 and the finite difference curve 1006, respectively. Determined analytically, the maximum channel temperature is 324 K at a distance of 0.246 μm from the source end; and the temperature at the pinch-off point is 323.25 K at a distance of 0.215 μm from the source end.

As evident from FIGS. 10(a) to (j), the analytical and finite difference approaches correspond to a high degree so long as a sufficiently small step size is used when using the finite difference approach.

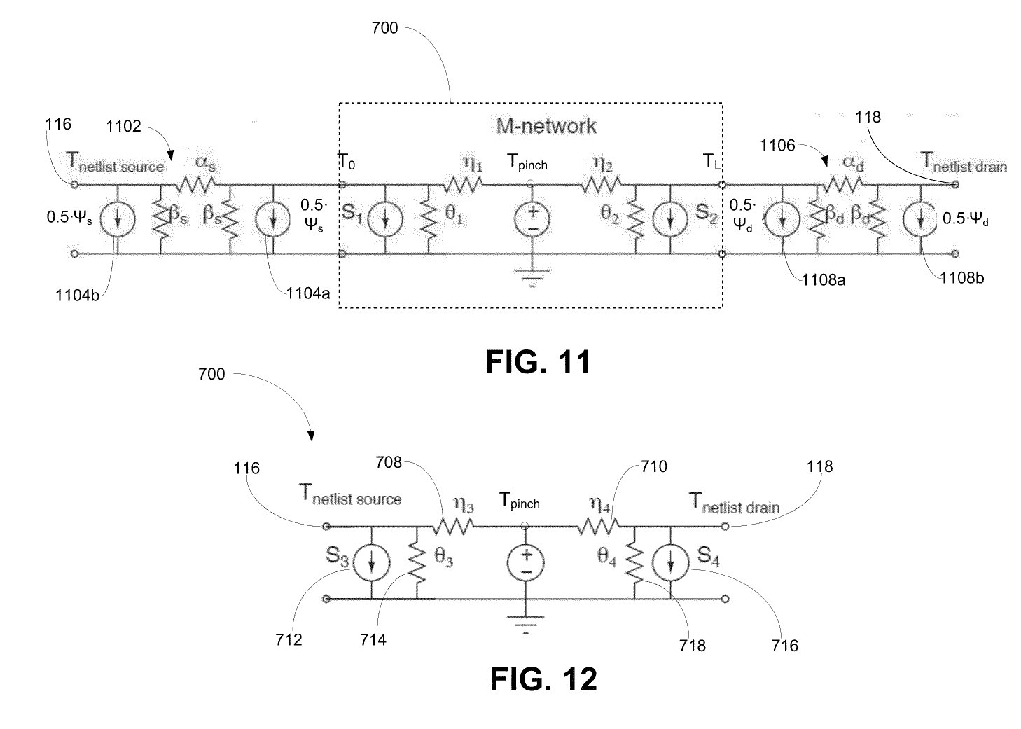

Referring now to FIG. 11, there is shown another embodiment in which the M-Network 700 is expanded so that the MOSFET 100 is modeled from its source netlist node 116 to its drain netlist node 118, instead of only from the source end 110 to the drain end 112 of the channel 104, as is done in FIG. 7. Connected across the source end node 724 and the common node 720 of the M-Network 700 are a pair of current sources 1104a,b between which is connected a resistive pi network 1102; these current sources 1104a,b and the pi network 1102 thermally model the portion of the MOSFET 100 between the source end 110 of the channel 104 and the source netlist node 116. Similarly, connected across the drain end node 726 and the common node 720 are another pair of current sources 1108a,b and another resistive pi network 1106; these current sources 1108a,b and the pi network 1106 thermally model the portion of the MOSFET 100 between the drain end 112 of the channel 104 and the drain netlist node 118. The magnitude of each of the current sources 1104a,b connected to the source end node 724 is 0.5·ψₛ, while the resistors in the pi network 1102 have resistances of αₛ, βₛ, and βₛ. Similarly, each of the current sources 1108a,b connected to the drain end node 726 is 0.5·ψ_{d}, while the resistors in the pi network 1106 have resistances of α_{d}, β_{d}, and β_{d}. The circuit shown in FIG. 11 can be simplified to result in the embodiment of the M-Network 700 shown in FIG. 12, which is structurally identical to the embodiment of the M-Network 700 of FIG. 7 but whose components instead have the following magnitudes:

$${η}_{4} = \frac{{α}_{d} {η}_{2}}{{α}_{d} + {β}_{d} + {θ}_{2} + {η}_{2}}$$

$${η}_{3} = \frac{{α}_{2} {η}_{2}}{{α}_{s} + {β}_{s} + {θ}_{1} + {η}_{1}}$$

$${θ}_{4} = {β}_{d} + \frac{{α}_{d} ( {β}_{2} + {θ}_{2} )}{{α}_{d} + {β}_{d} + {θ}_{2} + {η}_{2}}$$

$${θ}_{3} = {β}_{d} + \frac{{α}_{s} ( {β}_{s} + {θ}_{s} )}{{α}_{s} + {β}_{s} + {θ}_{1} + {η}_{1}}$$

$${S}_{4} = \frac{{α}_{d} ( {S}_{2} - {ψ}_{d} ) - 0.5 {ψ}_{d} ( {β}_{d} + {θ}_{2} + {η}_{2} )}{{α}_{d} + {β}_{d} + {θ}_{2} + {η}_{2}}$$

$${S}_{3} = \frac{{α}_{s} ( {S}_{1} - {ψ}_{s} ) - 0.5 {ψ}_{s} ( {β}_{s} + {θ}_{1} + {η}_{1} )}{{α}_{s} + {β}_{s} + {θ}_{1} + {η}_{1}}$$

The voltages, and accordingly the temperatures, at the source and drain netlist nodes 116,118 are respectively labelled T_{netlist source} and T_{netlist drain} in FIGS. 11 and 12.

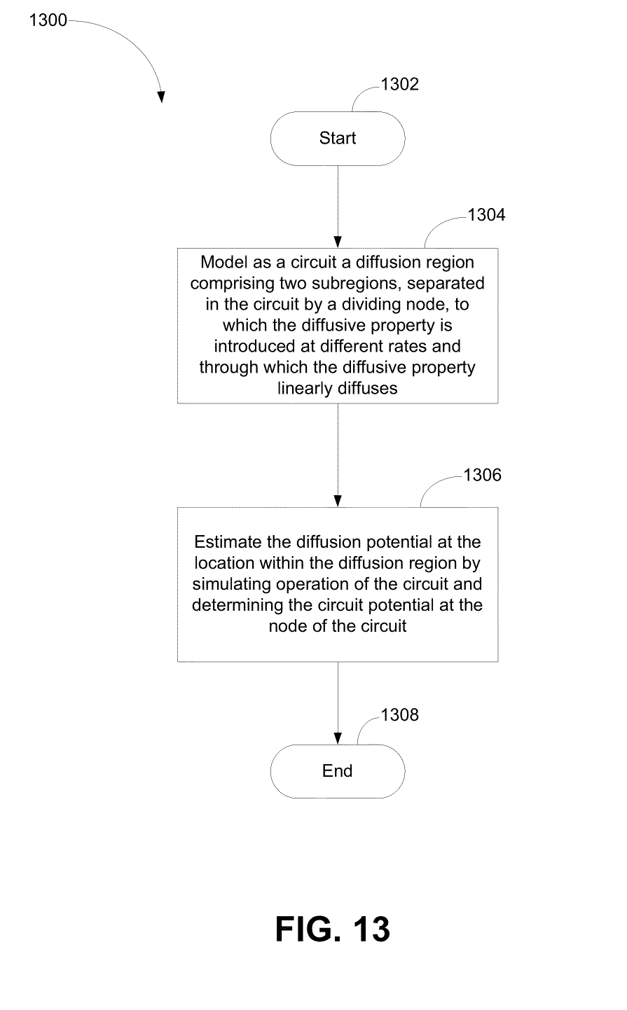

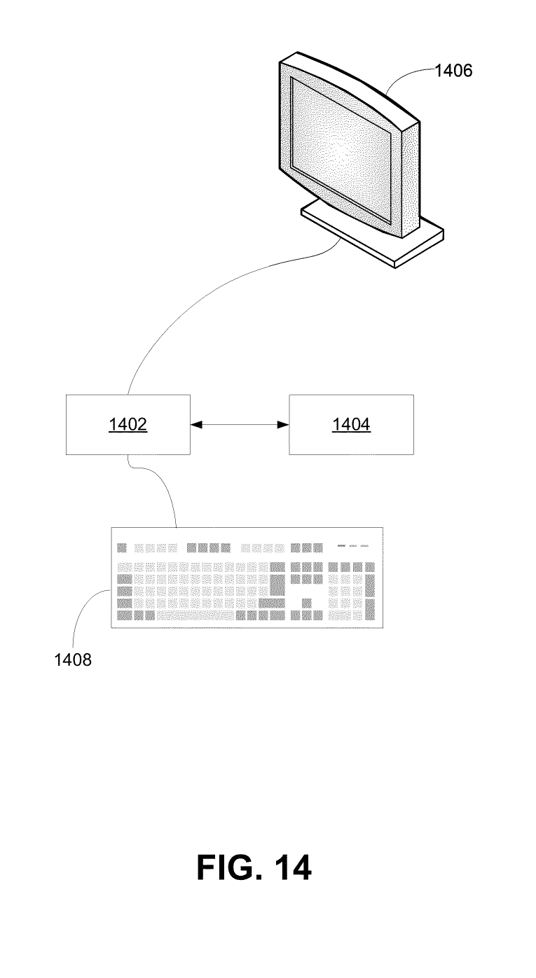

Referring now to FIGS. 13 and 14, there are respectively shown an embodiment of a method 1300 for estimating a diffusion potential of a diffusive property, and an embodiment of a system 1400 for estimating a diffusion potential of a diffusive property. The system 1400 includes a controller 1402; a computer readable medium 1404 that is communicatively coupled to the controller 1402; a display 1406 that is communicatively coupled to the controller 1402; and an input device, such as a keyboard 1408, that is communicatively coupled to the controller 1402.

The method 1300 is encoded on to the computer readable medium 1404, and the controller 1402 accordingly performs the method 1300. At block 1302 the controller 1402 begins performing the method 1300, and proceeds immediately to block 1304. At block 1304 the controller 1402 models a portion of the diffusion region, such as the channel 104 of the MOSFET 100, using a circuit, such as the M-Network 700. While the depicted embodiment of the M-Network 700 is an electrical circuit, in alternative embodiments (not depicted) the M-Network 700 may be, for example, a thermal circuit, a pneumatic circuit, or a hydraulic circuit. Depending on the embodiment, the particular circuit potential of the M-Network 700 that corresponds to the diffusion potential may vary. For example, when the M-Network 700 is an electrical circuit as it is in FIG. 7, the circuit potential that corresponds to the diffusion potential is voltage. As another example, in an embodiment in which the M-Network 700 is a hydraulic circuit, the circuit potential is pressure.

After the diffusion region is modeled using the M-Network 700, the controller 1402 proceeds to block 1304 and simulates operation of the M-Network 700 to determine the circuit potentials at various nodes at the M-Network 700; as noted above, as the M-Network in the depicted embodiment is an electrical circuit, the voltages at the various nodes of the M-Network 700 correspond to the temperature at various locations within the diffusion region of the MOSFET 700. Simulation may be performed using a circuit simulator such as SPICE. In the embodiment of the M-Network 700 of FIG. 7, the diffusion region is the channel 104 of the MOSFET 100; in the embodiment of the M-Network of FIG. 12, the diffusion region is the channel 104 and the portions of the MOSFET 100 between the source and drain ends 110,112 and the source and drain netlist nodes 116,118. The controller 1402 utilizes the following input variables, which a user can supply via the keyboard 1408:
(a) the temperatures at the source end 110 and the drain end 112 or at the source and drain netlist nodes 116,118;
(b) the temperature of the substrate 306, which acts as T^{ref};
(c) gate voltage (V_{gs});
(d) drain voltage (Vₐₛ);
(e) substrate bias voltage (V_{bs}); and
(f) a netlist extracted from layout of the IC.

The controller 1402 outputs any one or more of the following in a text file or on the display 1406, for example:
(a) the temperature distribution along the length of the channel 104;
(b) drain current (I_{ds});
(c) average thermal conductance;
(d) average channel temperature;
(e) maximum channel temperature;
(f) the temperature at the pinch-off point 114; and
(g) the effective length and width of the channel.

The controller 1402 subsequently proceeds to block 1306, where the method 1300 ends.

Beneficially, the foregoing method 1300 and system 1400 allow a netlist to be used to model operation of a diffusion region, such as between the source and drain netlist nodes 116,118 of the MOSFET 100, in multiple physical domains. For example, with respect to the MOSFET 100, a netlist is conventionally used to model the MOSFET 100's behaviour in the electrical domain, and the method 1300 and system 1400 also allow a netlist to be used to model the MOSFET 100 in the thermal domain. This can potentially be advantageous for several reasons. One potential advantage is rapid solution: problem matrices in the different domains have a common sparsity pattern whose solution topology can be determined once (a computationally expensive procedure) and then re-used for all physical domains to achieve faster calculation. MOSFET channels 104 are commonly described electrically by resistors, the simplest form of two-port network. The electric circuit topology of a VLSI circuit can thus be re-used, courtesy of the M-network 700, to determine the temperature profile in the same circuit, including the temperature profile within MOSFET devices. Anything other than a thermal-domain two-port network to describe the MOSFET channel 104 would require a costly reformulation of the matrix problem for the thermal domain. Another potential advantage is repurposing of electrical parasitic extraction software tools and component descriptions in the thermal domain. Each extracted circuit component (resistor, capacitor, MOSFET) can have two-port electrical and thermal domain interpretations. The M-Network 700 can be used to improve the accuracy of thermal analysis of MOSFET devices within VLSI circuits over the accuracy of a pi-network model of the channel 104, but does not require information beyond that which is reasonably available from a parasitic extraction and standard device models.

While the foregoing embodiments are directed at modeling a single diffusion region that is divided into two subregions, in alternative embodiments (not depicted) multiple diffusion regions can be modeled. For example, in an embodiment in which a collection of MOSFETs 100 are electrically coupled together, the channel 104 of each of the MOSFETs 100 may be thermally modeled using one M-Network 700, and the M-Networks 700 of each of the MOSFETs may be coupled together to model the collection of MOSFETs 100.

The controller 1402 may be any suitable type of controller, such as a processor, microcontroller, programmable logic controller, field programmable gate array, or can be implemented in hardware using, for example, an application-specific integrated circuit. Exemplary computer readable media include disc-based media such as CD-ROMs and DVDs, magnetic media such as hard drives and other forms of magnetic disk storage, semiconductor based media such as flash media, random access memory, and read only memory.

For the sake of convenience, the example embodiments above are described as various interconnected functional blocks or distinct software modules. This is not necessary, however, and there may be cases where these functional blocks or modules are equivalently aggregated into a single logic device, program or operation with unclear boundaries. In any event, the functional blocks or software modules can be implemented by themselves, or in combination with other operations in either hardware or software.

It is contemplated that any part of any aspect or embodiment discussed in this specification can be implemented or combined with any part of any other aspect or embodiment discussed in this specification.

While particular embodiments have been described in the foregoing, it is to be understood that other embodiments are possible and are intended to be included herein. It will be clear to any person skilled in the art that modifications of and adjustments to the foregoing embodiments, not shown, are possible. The scope of the claims should not be limited by the embodiments set forth in the examples, but should be given the broadest possible interpretation consistent with the description as a whole.

1. A method for estimating a diffusion potential of a diffusive property, the method comprising:
(a) modeling as a circuit a diffusion region comprising two subregions to which the diffusive property is introduced at different rates and through which the diffusive property linearly diffuses, wherein nodes of the circuit comprise a dividing node dividing branches of the circuit modeling the two subregions and wherein a circuit potential at one of the nodes of the circuit corresponds to the diffusion potential at a location within the diffusion region; and
(b) estimating the diffusion potential at the location within the diffusion region by simulating operation of the circuit and determining the circuit potential at the one of the nodes of the circuit.

2. A method as claimed in claim 1, wherein the diffusive property is steady-state heat.

3. A method as claimed in claim 1, wherein the diffusion region is a pinched-off channel of a MOSFET.

4. A method as claimed in claim 1, wherein the circuit is selected from the group consisting of an electric circuit, a pneumatic circuit, a hydraulic circuit, and a thermal circuit.

5. A method as claimed in claim 3, wherein the circuit is an electric circuit.

6. A method as claimed in claim 5, wherein the channel comprises a pinch-off point and wherein the electric circuit comprises:
(a) a voltage source connected between a common node and the dividing node, the dividing node corresponding to the pinch-off point of the channel; and
(b) source and drain branches each connected in parallel between the pinch-off node and the common node, each of the source and drain branches comprising:
(i) a first resistor having one end connected to the pinch-off node; and
(\ddot{υ}) a parallel branch comprising a current source and a second resistor connected together in parallel, the parallel branch connected in series between the other end of the first resistor and the common node.

7. A method as claimed in claim 6, wherein the node between the first resistor of the source branch and the parallel branch of the source branch corresponds to the source end of the channel, and the node between the first resistor of the drain branch and the parallel branch of the drain branch corresponds to the drain end of the channel.

8. A method as claimed in claim 6, further comprising modeling portions of the MOSFET between the source and drain ends of the channel and a source netlist node and a drain netlist node of the MOSFET, respectively, as a source netlist branch and a drain netlist branch each comprising:
(a) a pair of current sources; and
(b) a resistive pi network connected in parallel between the pair of current sources, wherein the pair of current sources and the resistive pi network of the source netlist branch are connected in parallel across the source branch and the pair of current sources and the resistive pi network of the drain netlist branch are connected in parallel across the drain branch.

9. A method as claimed in claim 6, wherein the node between the first resistor of the source branch and the parallel branch of the source branch corresponds to a source netlist node of the MOSFET, and the node between the first resistor of the drain branch and the parallel branch of the drain branch corresponds to a drain netlist node of the MOSFET.

10. A method as claimed in claim 1, further comprising, following estimating the diffusion potential at the location within the diffusion region, analytically determining the diffusion potential at an additional location within the diffusion region that corresponds to positions between the nodes of the circuit.

11. A method as claimed in claim 1, wherein each of the nodes of the circuit corresponds to the diffusion potential at a different location within the diffusion region.

12. A method as claimed in claim 1, wherein the diffusive property is generated within the diffusion region.

13. A method as claimed in claim 1, wherein the diffusive property is transported to the diffusion region.

14. A method for estimating temperature within a channel of a MOSFET that is pinched-off at a pinch-off point, the method comprising:
(a) modeling the thermal properties of the channel as an electric circuit comprising a dividing node corresponding to the pinch-off point of the channel and branches modeling subregions of the channel separated from each other by the pinch-off point, wherein the dividing node is one of multiple nodes of the circuit and wherein a voltage at one of the nodes of the circuit corresponds to the temperature at a location within the channel; and
(b) estimating the temperature at the location within the channel by simulating operation of the circuit and determining the voltage at the one of the nodes of the circuit.

15. A system for estimating a diffusion potential of a diffusive property, the system comprising:
(a) a controller; and
(b) a computer readable medium, communicatively coupled to the controller, and having encoded thereon statements and instructions to cause the controller to perform a method, the method comprising:
(i) modeling as a circuit a diffusion region comprising two subregions to which the diffusive property is introduced at different rates and through which the diffusive property linearly diffuses, wherein nodes of the circuit comprise a dividing node dividing branches of the circuit modeling the two subregions and wherein a circuit potential at one of the nodes of the circuit corresponds to the diffusion potential at a location within the diffusion region; and
(ii) estimating the diffusion potential at the location within the diffusion region by simulating operation of the circuit and determining the circuit potential at the one of the nodes of the circuit.

16. A computer readable medium having encoded thereon statements and instructions to cause a controller to perform a method as claimed in claim 1.

17. A system for estimating a diffusion potential of a diffusive property, the system comprising:
(a) a controller; and
(b) a computer readable medium, communicatively coupled to the controller, and having encoded thereon statements and instructions to cause the controller to perform a method, the method comprising:
(i) modeling the thermal properties of the channel as an electric circuit comprising a dividing node corresponding to the pinch-off point of the channel and branches modeling subregions of the channel separated from each other by the pinch-off point, wherein the dividing node is one of multiple nodes of the circuit and wherein a voltage at one of the nodes of the circuit corresponds to the temperature at a location within the channel; and
(ii) estimating the temperature at the location within the channel by simulating operation of the circuit and determining the voltage at the one of the nodes of the circuit

18. A computer readable medium having encoded thereon statements and instructions to cause a controller to perform a method as claimed in claim 14.
